(19) United States
(12) Patent Application Publication
(10) Pub. No.: US 2026/0150758 A1
(43) Pub. Date: May 28, 2026

(54) SEMICONDUCTOR PACKAGE

(71) Applicant: SAMSUNG ELECTRONICS CO., LTD., Suwon-si (KR)

(72) Inventor: Juhyeon Oh, Suwon-si (KR)

(73) Assignee: SAMSUNG ELECTRONICS CO., LTD., Suwon-si (KR)

(21) Appl. No.: 19/240,658

(22) Filed: Jun. 17, 2025

(30) Foreign Application Priority Data
Nov. 27, 2024 (KR) 10-2024-0172770

(51) Int. Cl. H01L 25/16; G02B 6/12; H01L 23/00; H01L 23/522

(52) U.S. Cl. CPC H10W 90/00; G02B 6/12; H10W 20/42; H10W 72/944

(57) ABSTRACT

Provided is a semiconductor package including a redistribution substrate, an electronic integrated circuit (EIC) chip on the redistribution substrate, an optical path bridge chip on the redistribution substrate, the optical path bridge chip on the EIC chip in a horizontal direction and including a first waveguide (WG) extending in the horizontal direction, a photonic integrated circuit (PIC) chip on the EIC chip and the optical path bridge chip, the PIC chip including a second WG extending in the horizontal direction, and a transparent support layer on the PIC chip, wherein a portion of the first WG overlaps a portion of the second WG in a vertical direction, and wherein the PIC chip is configured to provide an optical signal to be transmitted external to the semiconductor package through the second WG, the first WG, and the transparent support layer.

### CROSS-REFERENCE TO RELATED APPLICATION

This application claims priority to Korean Patent Application No. 10-2024-0172770, filed on Nov. 27, 2024, in the Korean Intellectual Property Office, the disclosure of which is incorporated by reference herein in its entirety.

### BACKGROUND

Embodiments of the present disclosure relate to a semiconductor package, and more particularly, to a semiconductor package including a photonic integrated circuit (PIC) chip.

With the development of the electronics industry, electronic components have increasingly been required to be relatively high functionalized and miniaturized and have high speed. With this trend, the need for miniaturization and multifunctionalization of semiconductor chips used in electronic parts has increased. In addition, in the field of semiconductor packages, the size is being reduced based on compact semiconductor chips. Furthermore, due to the demand for improved performance and reduced form factor of semiconductor packages, semiconductor package structures are moving toward multi-chip integrated structures. Multi-chip integration refers to integrating chips having different functions together into a single semiconductor package. Recently, PIC chips and electronic integrated circuit (EIC) chips have been integrated into a single semiconductor package.

### SUMMARY

One or more embodiments provide a semiconductor package including an electronic integrated circuit (EIC) chip and a photonic integrated circuit (PIC) chip in a structure, which is highly compatible with semiconductor package processes and facilitates transmission of optical signals, and a method of manufacturing the semiconductor package.

According to an aspect of one or more embodiments, there is provided a semiconductor package including a redistribution substrate, an electronic integrated circuit (EIC) chip on the redistribution substrate, an optical path bridge chip on the redistribution substrate, the optical path bridge chip on the EIC chip in a horizontal direction and including a first waveguide (WG) extending in the horizontal direction, a photonic integrated circuit (PIC) chip on the EIC chip and the optical path bridge chip, the PIC chip including a second WG extending in the horizontal direction, and a transparent support layer on the PIC chip, wherein a portion of the first WG overlaps a portion of the second WG in a vertical direction, and wherein the PIC chip is configured to provide an optical signal to be transmitted external to the semiconductor package through the second WG, the first WG, and the transparent support layer.

According to another aspect of one or more embodiments, there is provided a semiconductor package including a redistribution substrate, an electronic integrated circuit (EIC) chip on the redistribution substrate, the EIC chip including a through electrode, an optical path bridge chip on the redistribution substrate, the optical path bridge chip on the EIC chip in a horizontal direction and including a first waveguide (WG) extending in the horizontal direction, a photonic integrated circuit (PIC) chip on the EIC chip and the optical path bridge chip, the PIC chip including a second WG extending in the horizontal direction, a multi-insulating layer on the EIC chip, the optical path bridge chip, and the PIC chip, and a transparent support layer on the PIC chip and the multi-insulating layer, wherein a portion of the first WG overlaps a portion of the second WG in a vertical direction, wherein the PIC chip is configured to provide an optical signal to be transmitted external to the semiconductor package through the second WG, the first WG, the multi-insulating layer, and the transparent support layer, and wherein the through electrode is configured to transmit an electronic signal between the PIC chip and the EIC chip.

According to still another aspect of one or more embodiments, there is provided a semiconductor package including a base substrate, a first semiconductor device on the base substrate, a second semiconductor device on the base substrate and a left side of the first semiconductor device in a horizontal direction, and a first optical communication package on the base substrate and a right side of the first semiconductor device in the horizontal direction, the first optical communication package being configured to perform optical communication, wherein the first optical communication package includes a redistribution substrate, an electronic integrated circuit (EIC) chip on the redistribution substrate, an optical path bridge chip on the redistribution substrate, the optical path bridge chip on the EIC chip in the horizontal direction and including a first waveguide (WG) extending in the horizontal direction, a photonic integrated circuit (PIC) chip on the EIC chip and the optical path bridge chip, the PIC chip including a second WG extending in the horizontal direction, a multi-insulating layer on the EIC chip, the optical path bridge chip, and the PIC chip, and a transparent support layer on the PIC chip and the multi-insulating layer, wherein a portion of the first WG overlaps a portion of the second WG in a vertical direction, and wherein the PIC chip is configured to provide an optical signal to be transmitted to external to the semiconductor package through the second WG, the first WG, the multi-insulating layer, and the transparent support layer.

According to still another aspect of one or more embodiments, there is provided a method of manufacturing a semiconductor package, the method including forming a transparent support layer, forming a photonic integrated circuit (PIC) chip on the transparent support layer, the PIC chip including a first waveguide (WG) extending in a horizontal direction, forming an electronic integrated circuit (EIC) chip on the PIC chip, and forming an optical path bridge chip on the PIC chip and at a side of the EIC chip in the horizontal direction, the optical path bridge chip including a second WG extending in the horizontal direction, wherein a portion of the first WG overlaps a portion of the second WG in a vertical direction, and wherein the PIC chip is configured to provide an optical signal to be transmitted to an outside of the semiconductor package through the first WG, the second WG, and the transparent support layer.

The method may further include forming a reflector in the optical path bridge chip, the reflector being on the second WG in the horizontal direction and being configured to reflect the optical signal in the vertical direction to be incident to the transparent support layer.

The forming of the EIC chip may include forming a first body layer, an active layer on a first surface the first body layer, forming a lower pad on a second surface of the first body layer, forming an upper pad on a first surface of the active layer, forming a through electrode passing through the first body layer and connecting the lower pad to the active layer, and forming a chip pad in the PIC chip is connected to the upper pad.

The forming the chip pad may include forming the chip pad to be connected to the upper pad through one of hybrid copper bonding (HCB) and a connection terminal.

The forming of the PIC chip may include forming a second body layer, forming a buried oxide (BOX) layer on a surface of the second body layer, forming an optical passive device in the BOX layer, the second WG being in the BOX layer, and a chip pad on a surface of the BOX layer, and wherein the chip pad is on a portion of the bottom surface of the BOX layer overlapping the EIC chip in the vertical direction and connected to an upper pad of the EIC chip.

The method may further include forming a first insulating layer on transparent support layer and a side surface of the PIC chip, and forming a second insulating layer on the first insulating layer, the optical path bridge chip, and a side surface of the PIC chip, wherein the second insulating layer is transparent and is configured to provide an optical path from the optical path bridge chip to the transparent support layer.

The method may further include bonding the transparent support layer to the PIC chip via a bonding interface layer, wherein the transparent support layer may include an anti-reflective layer at a bottom of the transparent support layer.

The method may further include forming an optical coupler in the transparent support layer that is connected to an optical fiber, wherein the optical coupler is configured to transmit the optical signal to the optical fiber.

### BRIEF DESCRIPTION OF DRAWINGS

Embodiments will be more clearly understood from the following detailed description taken in conjunction with the accompanying drawings in which:

FIG. 1 is a cross-sectional view of a semiconductor package according to one or more embodiments;

FIGS. 2A, 2B, and 2C are a perspective view and plan views of a coupling structure of a first waveguide of an optical path bridge chip and a second waveguide of a photonic integrated circuit (PIC) chip in the semiconductor package of FIG. 1;

FIG. 3 is a cross-sectional view of a semiconductor package according to one or more embodiments;

FIG. 4 is a cross-sectional view of a system package according to one or more embodiments;

FIGS. 5A, 5B, and 5C are detailed cross-sectional views showing the structures of a second semiconductor device of a semiconductor package in FIG. 4;

FIGS. 6 and 7 are cross-sectional views of system packages according to one or more embodiments;

FIGS. 8A, 8B, 8C, 8D, 8E, 8F, 8G, 8H, 8I, 8J, 8K, and 8L are schematic cross-sectional views of stages in a method of manufacturing a semiconductor package, according to one or more embodiments; and

FIGS. 9A, 9B, 9C, 9D, 9E, 9F, 9G, 9H, and 9I are schematic cross-sectional views of stages in a method of manufacturing an optical path bridge chip, according to one or more embodiments.

### DETAILED DESCRIPTION

Hereinafter, embodiments will be described in detail with reference to the accompanying drawings. In the drawings, like reference characters denote like elements, and redundant descriptions thereof will be omitted.

It will be understood that, although the terms first, second, third, fourth, etc. may be used herein to describe various elements, components, regions, layers and/or sections (collectively “elements”), these elements should not be limited by these terms. These terms are only used to distinguish one element from another element. Thus, a first element described in this description section may be termed a second element or vice versa in the claim section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

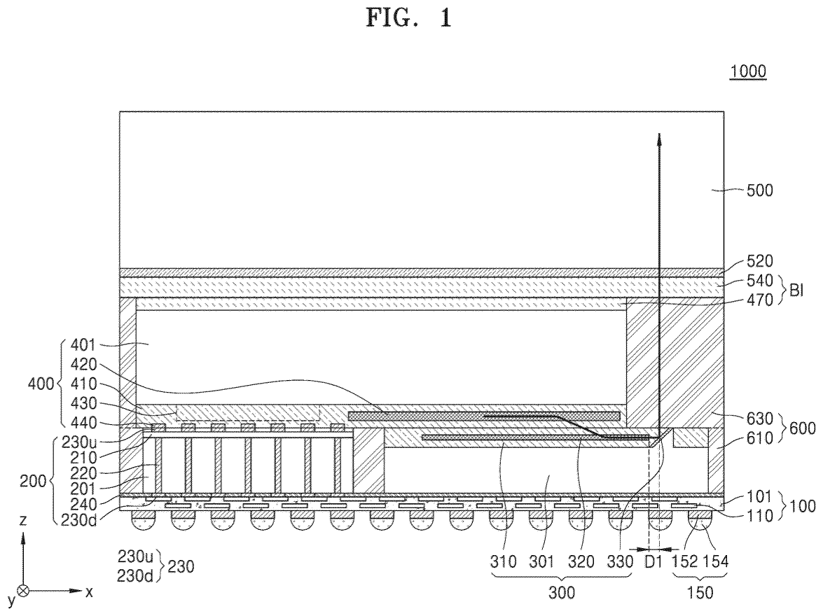

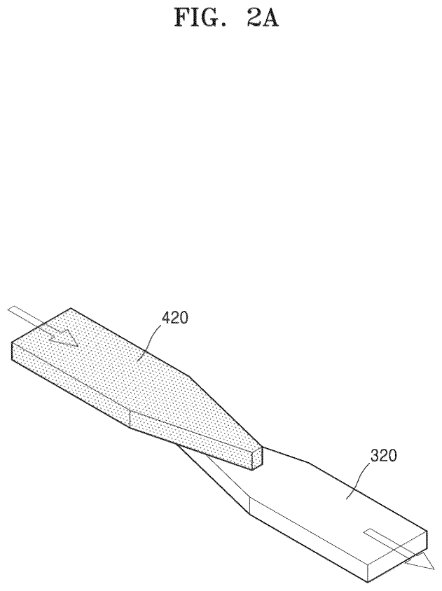

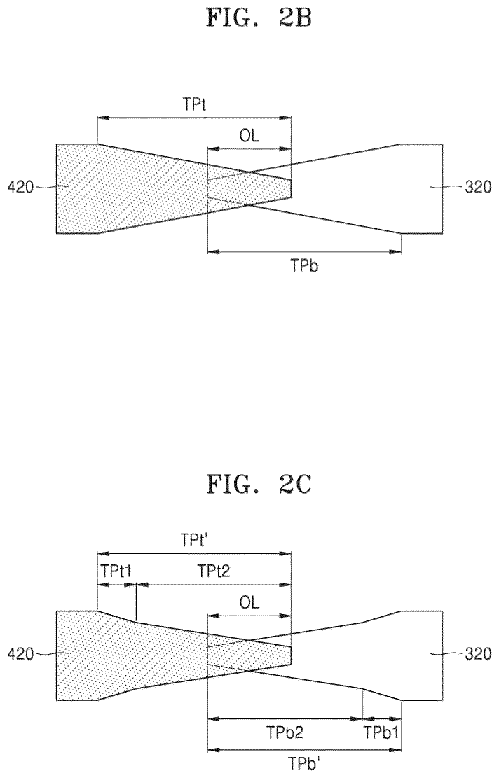

FIG. 1 is a cross-sectional view of a semiconductor package according to one or more embodiments. FIGS. 2A to 2C are a perspective view and plan views of a coupling structure of a first waveguide (WG) of an optical path bridge chip and a second WG of a photonic integrated circuit (PIC) chip in the semiconductor package of FIG. 1.

Referring to FIGS. 1 to 2C, a semiconductor package 1000 of one or more embodiments may correspond to a semiconductor package for co-packaged optics (CPO). CPO is heterogeneous integration technology that integrates an optical engine (or an optical module) and a switch semiconductor chip into a single package substrate. Recently, with the advent of the artificial intelligence (AI) era, much research and development has been conducted on CPO for an ultrahigh-speed, high-efficient data computing process.

The semiconductor package 1000 of one or more embodiments may include a redistribution substrate 100, an electronic integrated circuit (EIC) chip 200, an optical path bridge chip 300, a PIC chip 400, and a transparent support layer 500. The redistribution substrate 100 may be arranged below the EIC chip 200 and the optical path bridge chip 300 and may redistribute a pad of the EIC chip 200 to a region outside the EIC chip 200. For example, the redistribution substrate 100 may correspond to a fan-out redistribution substrate used to expand the footprint of the EIC chip 200. For example, the redistribution substrate 100 may include a redistribution body layer 101 and a redistribution line 110. The redistribution line 110 may be formed in multiple layers. Redistribution lines 110 in different layers may be connected to each other through a via.

The redistribution body layer 101 may include an insulating material, e.g., photo-imageable dielectric (PID) resin, and may further include an inorganic filler. However, the material of the redistribution body layer 101 is not limited to those mentioned above. The redistribution body layer 101 may have a multi-layer structure according to a multi-layer structure of the redistribution line 110. However, for convenience, it is illustrated in FIG. 1 that the redistribution body layer 101 has a single-layer structure. When the redistribution body layer 101 has a multi-layer structure, the redistribution body layer 101 may include only one material, or at least one layer may include a different material than the other layers.

A first external connection terminal 150 may be arranged on the bottom surface of the redistribution body layer 101. The first external connection terminal 150 may be arranged on a substrate pad on the bottom surface of the redistribution body layer 101. The first external connection terminal 150 may be electrically and/or physically connected to the redistribution line 110 of the redistribution substrate 100.

The first external connection terminal 150 may be arranged on a portion of the redistribution substrate 100, which corresponds to the bottom surface of the EIC chip 200, and a portion of the redistribution substrate 100, which extends in an x-direction and a y-direction on the bottom surface of the EIC chip 200. Consequently, the redistribution substrate 100 may redistribute a first pad 230 of the EIC chip 200 to a wider area than an area of the bottom surface of the EIC chip 200 through the redistribution line 110 and the first external connection terminal 150.

For example, the first external connection terminal 150 may include a pillar 152 and solder 154. However, embodiments are not limited thereto, and for example, the first external connection terminal 150 may include only the solder 154. For example, the pillar 152 may include nickel (Ni), copper (Cu), palladium (Pd), platinum (Pt), gold (Au), or a combination thereof. In one or more embodiments, the pillar 152 may operation as a pad and include Cu. Accordingly, the pillar 152 may be referred to as a bump pad, a Cu pad, or a Cu pillar. When the pillar 152 operates as a pad, a separate pad may not be formed on the bottom surface of the redistribution substrate 100.

The solder 154 may be arranged on the pillar 152. The solder 154 may include tin (Sn), indium (In), bismuth (Bi), antimony (Sb), copper (Cu), silver (Ag), zinc (Zn), and/or an alloy thereof. For example, the solder 154 may include Sn, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn, Sn—Bi—Zn, or the like. In some embodiments, the solder 154 may be referred to as a bump or a solder bump.

The EIC chip 200 may be mounted on the redistribution substrate 100. The EIC chip 200 may include a first body layer 201, an active layer 210, a through electrode 220, the first pad 230, and a protective layer 240. For example, the first body layer 201 may include a semiconductor element, such as silicon (Si) or germanium (Ge). The first body layer 201 may include a compound semiconductor, such as silicon carbide (SiC), gallium arsenide (GaAs), indium arsenide (InAs), or indium phosphide (InP). The first body layer 201 may have a silicon-on-insulator (SOI) structure. For example, the first body layer 201 may include a buried oxide (BOX) layer. The first body layer 201 may include a conductive region, e.g., an impurity-doped well or a structure such as an impurity-doped source/drain region. The first body layer 201 may include various isolation structures including a shallow trench isolation (STI) structure.

The active layer 210 may include an integrated circuit layer and a wiring layer on the integrated circuit layer. The integrated circuit layer may include various kinds of devices. For example, the integrated circuit layer may include various kinds of active devices and/or passive devices, such as a transistor, logic devices, memory devices, a system large scale integration (LSI), a complementary metal-oxide-semiconductor (CMOS) image sensor (CIS), and a micro-electro-mechanical system (MEMS).

In the semiconductor package 1000 according to one or more embodiments, various elements supporting the operation of the PIC chip 400 may be included in the integrated circuit layer of the active layer 210 of the EIC chip 200. For example, the integrated circuit layer of the EIC chip 200 may include a trans-impedance amplifier (TIA), a clock and data recovery (CDR) circuit, and at least one driver. In one or more embodiments, the TIA may be a sort of current-to-voltage converter and may include at least one operational amplifier. The TIA may amplify the current output of a photodetector or other type of sensor of the PIC chip 400 to a usable voltage. The TIA may provide low impedance to a photodiode of the PIC chip 400.

In one or more embodiments, the CDR circuit may extract timing information and data information from a serial data stream in the serial communication of digital data. In one or more embodiments, some relatively high-speed serial data streams may be transmitted without a clock signal. The CDR circuit may generate a clock signal from an appropriate frequency reference and then phase shift the clock signal to match the transition of a data stream. In one or more embodiments, the driver may be used to drive the various operations of the PIC chip 400.

The wiring layer may connect at least two devices to each other, connect devices to the conductive region of the first body layer 201, or connect devices to the through electrode 220. The wiring layer may also connect the through electrode 220 to the first pad 230, e.g., a first upper pad 230u. For example, the wiring layer may include wires and a contact or a via. In the EIC chip 200 of the semiconductor package 1000 of one or more embodiments, the active layer 210 may be arranged above the first body layer 201 and the through electrode 220. However, embodiments are not limited thereto, and for example, the active layer 210 may be arranged below the first body layer 201 and the through electrode 220.

The through electrode 220 may extend from the top to the bottom of the first body layer 201 through the first body layer 201. In one or more embodiments, the through electrode 220 may extend into the active layer 210. In the EIC chip 200 of the semiconductor package 1000 of one or more embodiments, the first body layer 201 may include Si, and accordingly, the through electrode 220 may correspond to a through-silicon via (TSV).

The through electrode 220 may have a pillar shape and include a barrier film on an outer surface thereof and a buried conductive layer therein. The barrier film may include at least one material selected from the group consisting of titanium (Ti), titanium nitride (TiN), tantalum (Ta), tantalum nitride (TaN), ruthenium (Ru), cobalt (Co), manganese (Mn), tungsten nitride (WN), nickel (Ni), and nickel boride (NiB). The buried conductive layer may include at least one material selected from the group consisting of copper (Cu), Cu alloys, such as copper tin (CuSn), copper magnesium (CuMg), copper nickel (CuNi), copper zinc (CuZn), copper palladium (CuPd), copper gold (CuAu), copper rhenium (CuRe), and copper tungsten (CuW), W, W alloys, Ni, Ru, and Co. An insulating layer may be between the through electrode 220 and the first body layer 201 or between the through electrode 220 and the active layer 210. For example, the insulating layer may include an oxide film, a nitride film, a carbide film, a polymer, or a combination thereof.

The first pad 230 may include the first upper pad 230u and a first lower pad 230d. The first lower pad 230d may be arranged on the bottom surface of the first body layer 201 and connected to the through electrode 220. The first upper pad 230u may be arranged on the top surface of the active layer 210 and connected to the wiring layer of the active layer 210. For example, the first pad 230 may include at least one selected from the group consisting of aluminum (Al), copper (Cu), nickel (Ni), tungsten (W), platinum (Pt), and gold (Au). In the EIC chip 200 of the semiconductor package 1000 of one or more embodiments, the first pad 230 may include Cu. However, the material of the first pad 230 is not limited to Cu.

The protective layer 240 may be arranged on the bottom surface of the first body layer 201. For example, the protective layer 240 may include an oxide film, a nitride film, a carbide film, a polymer, or a combination thereof. In the EIC chip 200 of the semiconductor package 1000 of one or more embodiments, the protective layer 240 may have a single-layer or multi-layer structure. The protective layer 240 may extend in a horizontal direction in the EIC chip 200 and cover the bottom surface of the optical path bridge chip 300 and the bottom surface of a multi-insulating layer 600, e.g., a first insulating layer 610. In one or more embodiments, due to this structure of the protective layer 240, the protective layer 240 may be excluded from the elements of the EIC chip 200.

The first lower pad 230d may pass through at least a portion of the protective layer 240. For example, the first lower pad 230d may pass through at least a portion of the protective layer 240 and may be buried in the protective layer 240. The first lower pad 230d may be on the bottom surface of the first body layer 201 or in the protective layer 240 and connected to the through electrode 220. The first upper pad 230u may be connected to a second pad 440 of the PIC chip 400. A protective layer may be arranged on the top surface of the active layer 210.

The optical path bridge chip 300 may be arranged on the redistribution substrate 100 and adjacent to the EIC chip 200. The optical path bridge chip 300 may provide a path for transmission of an optical signal from or to the PIC chip 400. The optical path bridge chip 300 may include a second body layer 301, a first BOX layer 310, a first WG 320, and a reflector 330.

For example, the second body layer 301 may include a semiconductor element, such as silicon (Si) or germanium (Ge). The second body layer 301 may include a compound semiconductor, such as silicon carbide (SiC), gallium arsenide (GaAs), indium arsenide (InAs), or indium phosphide (InP).

The first BOX layer 310 may be above the second body layer 301. For example, the first BOX layer 310 may include silicon oxide (SiO₂). However, the material of the first BOX layer 310 is not limited to SiO₂. The first WG 320 may be arranged inside the first BOX layer 310. The first WG 320 may extend in the x-direction. For example, the first WG 320 may include SiNx. However, the material of the first WG 320 is not limited to SiNx. For example, the first WG 320 may include Si. The first BOX layer 310 may correspond to a clad layer and the first WG 320 may correspond to a core layer.

The reflector 330 may be adjacent to an end of the first WG 320 in the x-direction. As shown in FIG. 1, the reflector 330 may not be in contact with the first WG 320 and may be spaced apart from the end of the first WG 320 by a first distance D1 in the x-direction. The reflector 330 may change the traveling direction of an optical signal from the horizontal direction into the vertical direction. The reflector 330 may include an oblique metal plate. For example, the top surface of the metal plate of the reflector 330 may be inclined at 45 degrees with respect to an optical signal traveling in the horizontal direction.

As an integrated circuit chip using light, the PIC chip 400 has recently been developed at an accelerated pace for transmission of large-capacity information, ultrahigh-speed signal processing, minimization of transmission loss, and minimization of energy consumption. The PIC chip 400 may be arranged on the EIC chip 200 and the optical path bridge chip 300. As shown in FIG. 1, in the vertical direction, e.g., the z-direction, the whole of the EIC chip 200 may overlap the PIC chip 400, and a portion of the optical path bridge chip 300 may overlap the PIC chip 400. However, embodiments are not limited thereto, and for example, only a portion of the EIC chip 200 may overlap the PIC chip 400 in the z-direction.

The PIC chip 400 may include a third body layer 401, a second BOX layer 410, a second WG 420, and an optical passive device region 430. For example, the third body layer 401 may include a semiconductor element, such as silicon (Si) or germanium (Ge). The third body layer 401 may include a compound semiconductor, such as silicon carbide (SiC), gallium arsenide (GaAs), indium arsenide (InAs), or indium phosphide (InP).

The second BOX layer 410 may be below the third body layer 401. For example, the second BOX layer 410 may include SiO₂. However, the material of the second BOX layer 410 is not limited to SiO₂. The second WG 420 may be arranged inside the second BOX layer 410. The second WG 420 may extend in the x-direction. For example, the second WG 420 may include SiNx. However, the material of the second WG 420 is not limited to SiNx. For example, the second WG 420 may include Si. In the concept of WG, the second BOX layer 410 may correspond to a clad layer and the second WG 420 may correspond to a core layer.

The optical passive device region 430 may also be inside the second BOX layer 410. Optical passive devices may be arranged in the optical passive device region 430. Here, an optical passive device may refer to any device that changes the characteristics of light. For example, optical passive devices may include a light source, a light-to-current converter, a filter, a duplexer, an optical coupler, an interferometer, a spectrometer, etc.

A wiring layer, a via, or a through electrode may be arranged below the optical passive device region 430. The second pad 440 may be arranged at the bottom of the PIC chip 400, which overlaps the EIC chip 200. The second pad 440 may be connected to the first pad 230, e.g. the first upper pad 230u, of the EIC chip 200. The second pad 440 may be connected to optical passive devices of the optical passive device region 430 through a wiring layer, a via, a through electrode, or the like.

Bonding between the second pad 440 of the PIC chip 400 and the first upper pad 230u of the EIC chip 200 may correspond to pad-to-pad bonding. In general, pads include Cu, and thus, pad-to-pad bonding is referred to as Cu-to-Cu bonding. The bonding between the second pad 440 and the first upper pad 230u may include insulator-to-insulator bonding in which a protective layer on the bottom surface of the PIC chip 400 and a protective layer on the top surface of the EIC chip 200 are bonded to each other. In this case, the PIC chip 400 and the EIC chip 200 may be bonded to each other through hybrid copper bonding (HCB). HCB may refer to a combination of pad-to-pad bonding and insulator-to-insulator bonding.

As shown by the solid line arrow, an optical signal from the PIC chip 400 may be transmitted through the second WG 420 and the first WG 320 of the optical path bridge chip 300, reflected by the reflector 330 in the vertical direction, and transmitted to the outside through the multi-insulating layer 600 and the transparent support layer 500.

The second WG 420 of the PIC chip 400 and the first WG 320 of the optical path bridge chip 300 may transmit an optical signal through evanescent coupling. Here, evanescent coupling is also referred to as evanescent field coupling. In a dielectric single-mode WG, an optical signal has an evanescent electromagnetic field that decays exponentially out of a core. Accordingly, when two single-mode WGs are arranged to be adjacent to each other, a WG mode may be excited by the evanescent field of an adjacent core, thereby enabling transmission of an optical signal.

FIGS. 2A to 2C show a structure for the evanescent coupling between the second WG 420 of the PIC chip 400 and the first WG 320 of the optical path bridge chip 300. FIG. 2A is a perspective view of an evanescent coupling structure, FIG. 2B is a plan view of the evanescent coupling structure of FIG. 2A, and FIG. 2C is a plan view of an evanescent coupling structure different from FIG. 2B. As seen in FIGS. 2A and 2B, the second WG 420 and the first WG 320 may have a tapered shape that thins toward an overlapping portion between the second WG 420 and the first WG 320. For example, the first WG 320 and the second WG 420 may respectively have tapered regions TPb and TPt, which may partially overlap each other in an overlapping region OL at end portions of the tapered regions TPb and TPt. Accordingly, as shown by the arrows in FIG. 2A, an optical signal may be transmitted from the second WG 420 to the first WG 320 through evanescent coupling. An optical signal may be transmitted in a reverse direction through evanescent coupling.

In the evanescent coupling structure of FIG. 2B, the tapered region TPb of the first WG 320 and the tapered region TPt of the second WG 420 may have a constant angle of inclination as a whole. However, embodiments are not limited thereto, and for example, in the evanescent coupling structure of FIG. 2C, a tapered region TPb′ of the first WG 320 may include a first tapered region TPb1 and a second tapered region TPb2, which may have different angles of inclination from each other. For example, the first tapered region TPb1 connected to the central portion of the first WG 320 may have a greater angle of inclination than an angle of inclination of the second tapered region TPb2. A tapered region TPt′ of the second WG 420 may include a first tapered region TPt1 and a second tapered region TPt2. The first tapered region TPt1 may have a greater angle of inclination than an angle of inclination of the second tapered region TPt2. In the evanescent coupling structure of FIG. 2C, the overlapping region OL may be formed in an end portion of each of the second tapered regions TPb2 and TPt2. This tapered evanescent coupling may be referred to as adiabatic coupling or adiabatic tapering in the sense that there is no loss.

In the semiconductor package 1000 of one or more embodiments, the coupling structure between the second WG 420 of the PIC chip 400 and the first WG 320 of the optical path bridge chip 300 is not limited to an evanescent coupling structure. For example, a butt coupling structure, in which the second WG 420 is in direct contact with the first WG 320, may be used.

The multi-insulating layer 600 may be arranged on the first redistribution substrate 100 and may be adjacent to and surround the EIC chip 200, the optical path bridge chip 300, and the PIC chip 400. The multi-insulating layer 600 may have a two-layer structure. For example, the multi-insulating layer 600 may include a first insulating layer 610 in a lower portion thereof and a second insulating layer 630 in an upper portion thereof. For example, the multi-insulating layer 600 may include SiO₂, silicon carbon nitride (SiCN), silicon oxynitride (SiON), SiN, or a polymer. However, the material of the multi-insulating layer 600 is not limited to those mentioned above. The multi-insulating layer 600 may be formed using a chemical vapor deposition (CVD) method or a spin coating method. However, a method of forming the multi-insulating layer 600 is not limited to those mentioned above.

The first insulating layer 610 may be arranged on the first redistribution substrate 100 and may surround the side surfaces of the EIC chip 200 and the optical path bridge chip 300. Due to manufacturing processes, a top surface of the first insulating layer 610 may be substantially coplanar with a top surfaces of the EIC chip 200 and the optical path bridge chip 300. The second insulating layer 630 may be arranged on the first insulating layer 610 and may be adjacent to and surround the side surface of the PIC chip 400. A top surface of the second insulating layer 630 may be substantially coplanar with a top surface of the PIC chip 400, e.g., a top surface of a first bonding interface 470.

A material of the first insulating layer 610 may be the same as or different from a material of the second insulating layer 630. Even when the material of the first insulating layer 610 is the same as the material of the second insulating layer 630, the first insulating layer 610 and the second insulating layer 630 may have different material characteristics from each other due to a difference in manufacturing processes. For example, when the first insulating layer 610 and the second insulating layer 630 are formed using CVD under different CVD process conditions, a stress characteristic may be controlled to be different between the first insulating layer 610 and the second insulating layer 630 in terms of compressive strength or tensile stress. As described above, when the first insulating layer 610 and the second insulating layer 630 include different materials from each other or are controlled to have different material characteristics through manufacturing processes, there may be a boundary surface between the first insulating layer 610 and the second insulating layer 630. In the semiconductor package 1000 of one or more embodiments, the warpage characteristic of the semiconductor package 1000 may be improved by adjusting the stress characteristic of the multi-insulating layer 600.

The second insulating layer 630 may provide an optical path. Accordingly, the second insulating layer 630 may include a transparent material, such as SiO₂. However, the material of the second insulating layer 630 is not limited to SiO₂. In one or more embodiments, a separate optical path block for an optical path may be arranged inside the second insulating layer 630.

The transparent support layer 500 may be arranged on the PIC chip 400 and the multi-insulating layer 600. The transparent support layer 500 may support main components, e.g., the EIC chip 200, the optical path bridge chip 300, and the PIC chip 400, of the semiconductor package 1000. The transparent support layer 500 may be attached to the PIC chip 400 and the multi-insulating layer 600 through a bonding interface BI. For example, the bonding interface BI may include the first bonding interface 470 on the top surface of the PIC chip 400 and a second bonding interface 540 on the bottom surface of the transparent support layer 500. As seen from the solid line arrow, an optical signal needs to pass through the bonding interface BI, and therefore, the bonding interface BI may include a transparent material, such as SiO₂ or SiCN. However, the material of the bonding interface BI is not limited to SiO₂ or SiCN.

In one or more embodiments, the transparent support layer 500 may dissipate heat, which is generated in the semiconductor package 1000, to the outside. In this case, to maximize the heat dissipation efficiency of the transparent support layer 500, the transparent support layer 500 may be attached to the PIC chip 400 and the multi-insulating layer 600 through a thermal interface material (TIM). The TIM is a sort of adhesive and may include a material that is transparent and has a satisfactory heat transfer characteristic. For example, the TIM may include SiO₂, a polymer TIM, thermal grease, optic glue, or the like.

The transparent support layer 500 may support optical communication of the PIC chip 400. Accordingly, the transparent support layer 500 may include a material that transmits light. For example, the transparent support layer 500 may include Si. However, the material of the transparent support layer 500 is not limited to Si. For example, the transparent support layer 500 may include SiO₂, glass, a transparent polymer, or the like. The transparent support layer 500 may include a transparent material other than those materials mentioned above. To minimize the reflection of an optical signal, an anti-reflective layer 520 may be arranged on the bottom surface of the transparent support layer 500. However, in some embodiments, the anti-reflective layer 520 may be omitted.

A microlens may be formed in the multi-insulating layer 600. An optical signal may be received and collected through the microlens and transmitted to the optical passive device region 430 of the PIC chip 400 through the reflector 330 and the first WG 320 of the optical path bridge chip 300 and the second WG 420 of the PIC chip 400. In one or more embodiments, the microlens may not be formed in the transparent support layer 500. In the case of a semiconductor package for CPO, the semiconductor package is combined with a fiber assembly unit (FAU) that transmits an optical signal. When a microlens is not formed in the transparent support layer 500, the microlens may be arranged inside the FAU.

The semiconductor package 1000 according to one or more embodiments may include the EIC chip 200, the PIC chip 400, and the optical path bridge chip 300 adjacent to the EIC chip 200. The optical path bridge chip 300 may include the first WG 320 and the reflector 330. The first WG 320 may be evanescent-coupled to the second WG 420 of the PIC chip 400. Accordingly, an optical signal from the PIC chip 400 may be transmitted to the first WG 320 through the evanescent coupling between the second WG 420 and the first WG 320, reflected by the reflector 330 in the vertical direction, and transmitted to the outside through an upper portion, e.g., the transparent support layer 500, of the semiconductor package 1000. Consequently, the semiconductor package 1000 of one or more embodiments may facilitate the transmission of an optical signal. In addition, the components of the semiconductor package 1000 of one or more embodiments may be more easily manufactured with compatibility with semiconductor package processes, and thus, the cost and yield of semiconductor packages may be significantly improved.

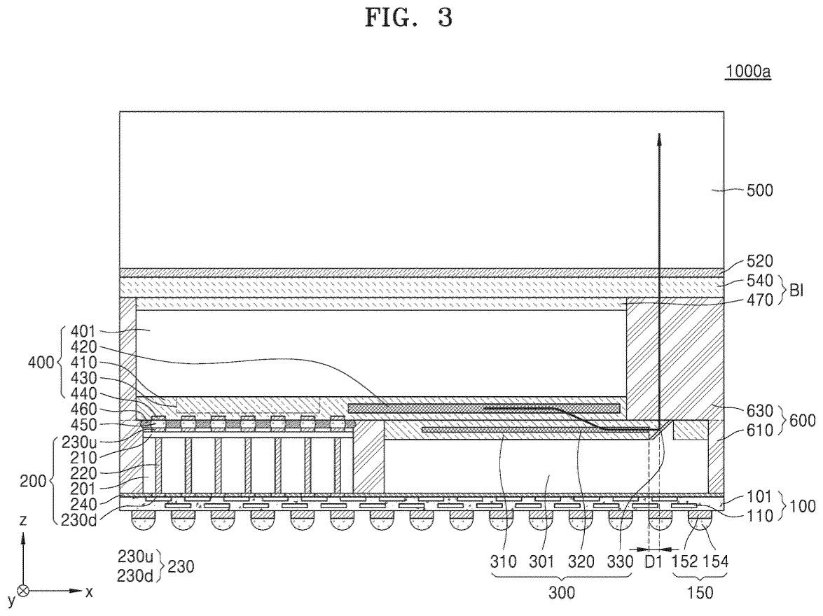

FIG. 3 is a cross-sectional view of a semiconductor package 1000a according to one or more embodiments. Redundant descriptions given above with reference to FIGS. 1 to 2C are brief or omitted.

Referring to FIG. 3, the semiconductor package 1000a of one or more embodiments may be different from the semiconductor package 1000 of FIG. 1 in the connection structure of the EIC chip 200 and the PIC chip 400. For example, the semiconductor package 1000a of one or more embodiments may include the first redistribution substrate 100, the EIC chip 200, the optical path bridge chip 300, the PIC chip 400, and the transparent support layer 500. The first redistribution substrate 100, the EIC chip 200, the optical path bridge chip 300, the PIC chip 400, and the transparent support layer 500 have been described in the descriptions of the semiconductor package 1000 of FIG. 1. However, because a connection terminal 450 is between the EIC chip 200 and the PIC chip 400, the optical path bridge chip 300 may become thicker by the height of the connection terminal 450.

In the semiconductor package 1000a of one or more embodiments, the PIC chip 400 may be connected to the EIC chip 200 through the connection terminal 450. For example, the connection terminal 450 may be between the first upper pad 230u of the EIC chip 200 and the second pad 440 of the PIC chip 400. For example, the connection terminal 450 may include solder. However, embodiments are not limited thereto, and for example, the connection terminal 450 may include a pillar and solder. The structure or material of the connection terminal 450 has been described in the description of the first external connection terminal 150 of the first redistribution substrate 100 of the semiconductor package 1000 of FIG. 1.

Because the PIC chip 400 is stacked on the EIC chip 200 through the connection terminal 450, an adhesive layer 460 may be arranged between the PIC chip 400 and the EIC chip 200. For example, the adhesive layer 460 may include a non-conductive film (NCF). An NCF is usually used as an adhesive layer when a semiconductor chip is bonded in a thermal compression bonding (TCB) manner in a semiconductor chip stacking process. However, in the semiconductor package 1000a of one or more embodiments, the material of the adhesive layer 460 is not limited to an NCF. In one or more embodiments, instead of the adhesive layer 460, an underfill may fill between the PIC chip 400 and the EIC chip 200.

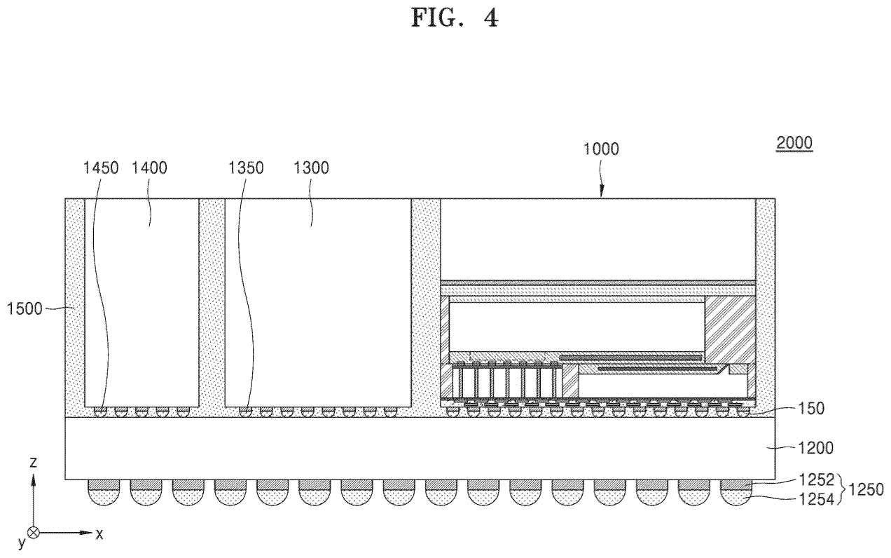

FIG. 4 is a cross-sectional view of a system package 2000 according to one or more embodiments. FIG. 1 is also referred to, and redundant descriptions already given with reference to FIGS. 1 to 3 are brief or omitted.

Referring to FIG. 4, the system package 2000 of one or more embodiments may include the semiconductor package 1000, a base substrate 1200, a first semiconductor device 1300, a second semiconductor device 1400, and a sealant 1500. The semiconductor package 1000 may correspond to the semiconductor package 1000 of FIG. 1. However, instead of the semiconductor package 1000 of FIG. 1, the semiconductor package 1000a of FIG. 3 may be applied to the system package 2000. The system package 2000 of one or more embodiments may also belong to a semiconductor package, system package may distinguish from the semiconductor package 1000 that is a component. The same concept may be applied to other system packages described below.

The base substrate 1200 may support the semiconductor package 1000, the first semiconductor device 1300, and the second semiconductor device 1400. The base substrate 1200 may correspond to an interposer or a package substrate. For example, in the system package 2000 of one or more embodiments, the base substrate 1200 may correspond to an interposer.

The semiconductor package 1000, the first semiconductor device 1300, and the second semiconductor device 1400 may be mounted on the base substrate 1200. For example, the first semiconductor device 1300 may be arranged on the central portion of the base substrate 1200 in the x-direction via a third external connection terminal 1350. The second semiconductor device 1400 may be arranged on the base substrate 1200 via a fourth external connection terminal 1450 and be on the left of the first semiconductor device 1300 in the x-direction. The semiconductor package 1000 may be arranged on the base substrate 1200 via the first external connection terminal 150 and be on the right of the first semiconductor device 1300 in the x-direction. However, embodiments are not limited thereto, and for example, the positions of the semiconductor package 1000, the first semiconductor device 1300, and the second semiconductor device 1400 on the base substrate 1200 may be changed.

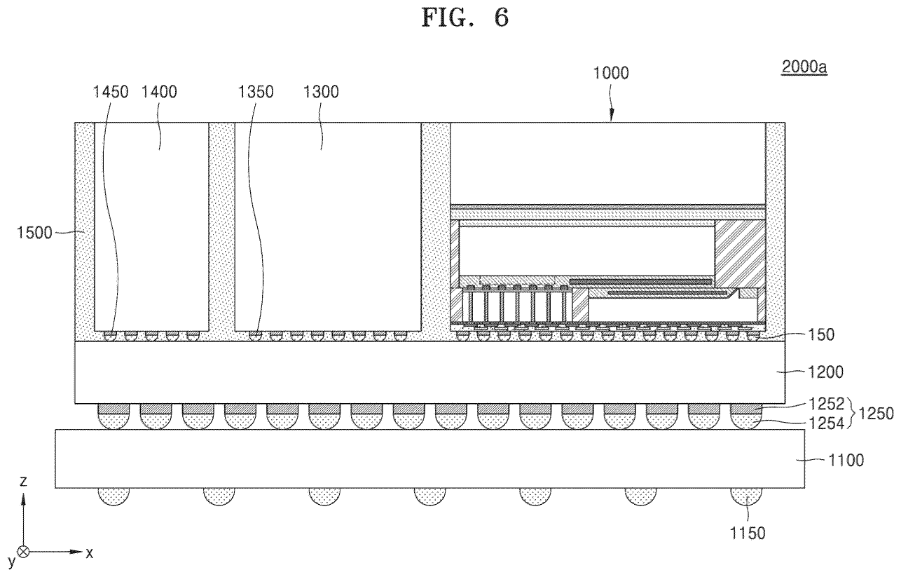

The base substrate 1200 may mediate signal transmission between the first semiconductor device 1300 and the second semiconductor device 1400 and signal transmission between each of the first and second semiconductor devices 1300 and 1400 and the semiconductor package 1000. The base substrate 1200 may be mounted on a package substrate (1100 in FIG. 6). In this case, the base substrate 1200 may mediate transmission of signals, power, and the ground between the semiconductor package 1000, the first semiconductor device 1300 or the second semiconductor device 1400 and the package substrate 1100. In the system package 2000 of one or more embodiments, the base substrate 1200 may correspond to a 2.5-dimensional (2.5D) interposer. Accordingly, the base substrate 1200 may include silicon (Si) and include a TSV therein. However, in the system package 2000 of one or more embodiments, the base substrate 1200 is not limited to the 2.5D interposer.

An interposer may include a 2.5D interposer and a 2.3D interposer. In one or more embodiments, an interposer structure may be subdivided by including an Si bridge. Accordingly, a structure except for a 2.5D interposer may be referred to as a 2.xD interposer. A 2.5D interposer may refer to an Si interposer and may include a TSV therein. A 2.3D interposer may refer to an organic or inorganic interposer. In the case of an organic interposer, polyimide, benzocyclobutene (BCB), or polybenzoxazole (PBO) may be used as a body layer. In the case of an inorganic interposer, ceramic or glass may be used as a body layer. When the 2.3D interposer includes a through electrode, the through electrode may be referred to as a through dielectric via (TDV) or a through glass via (TGV) according to the material of the body layer. In one or more embodiments, the 2.3D interposer may be referred to as a panel level package (PLP) interposer or a re-distribution layer (RDL) interposer.

The base substrate 1200 may include a base body, a through electrode, and a wiring layer. For example, the base body may include Si, and accordingly, the base substrate 1200 may correspond to an Si interposer. The through electrode may extend through the base body. Because the base body includes Si, the through electrode may correspond to a TSV. The through electrode may extend to the wiring layer through the base body and may be connected to wires of the wiring layer. In one or more embodiments, the base substrate 1200 may include only a wiring layer therein but not a through electrode. The wiring layer may be arranged in an upper portion or a lower portion of the base body or in both the upper and lower portions of the base body. A substrate pad may be arranged on the top and bottom surfaces of the base substrate 1200, and the through electrode may be connected to substrate pad directly or via the wiring layer.

A second external connection terminal 1250 may be arranged on the substrate pad on the bottom surface of the base substrate 1200 and electrically connected to the through electrode. The second external connection terminal 1250 may be connected to the substrate pad on the top surface of the base substrate 1200 via the through electrode and the wiring layer. As described above, the base substrate 1200 may be mounted on the package substrate 1100 via the second external connection terminal 1250. For example, the second external connection terminal 1250 may include a pillar 1252 and solder 1254. However, embodiments are not limited thereto, and for example, the second external connection terminal 1250 may include only solder. The material of the second external connection terminal 1250 has been described in the description of the first external connection terminal 150 of the first redistribution substrate 100 of the semiconductor package 1000 of FIG. 1.

In the system package 2000 of one or more embodiments, the base substrate 1200 may be used for transmission of electrical signals among the semiconductor package 1000, the first semiconductor device 1300, and the second semiconductor device 1400 or used to transmit power or the ground from the package substrate 1100 to the semiconductor package 1000, the first semiconductor device 1300, and the second semiconductor device 1400. Accordingly, the base substrate 1200 may not include devices, such as active devices or passive devices. However, embodiments are not limited thereto, and for example, the base substrate 1200 may include devices that control signal transmission.

The first semiconductor device 1300 may be mounted on the base substrate 1200 via the third external connection terminal 1350. As seen in FIG. 4, the first semiconductor device 1300 may be adjacent to the semiconductor package 1000 and arranged on the left portion of the base substrate 1200 in the x-direction. However, the first semiconductor device 1300 may be on the right of the second semiconductor device 1400 in the x-direction on the base substrate 1200. For example, the first semiconductor device 1300 may be between the semiconductor package 1000 and the second semiconductor device 1400 in the x-direction on the base substrate 1200. In one or more embodiments, the positions of the first semiconductor device 1300 and the second semiconductor device 1400 in the x-direction may be changed. For example, the second semiconductor device 1400 may be between the semiconductor package 1000 and the first semiconductor device 1300 in the x-direction on the base substrate 1200.

The first semiconductor device 1300 may include a logic chip. Accordingly, the first semiconductor device 1300 may include a plurality of logic devices therein. For example, logic devices may include an AND gate, a NAND gate, an OR gate, a NOR gate, an exclusive OR (XOR) gate, an exclusive NOR (XNOR) gate, an inverter (INV), an adder (ADD), a delay (DLY), a filter (FIL), a multiplexer (MXT/MXIT), an OR/AND/inverter (OAI) gate, an AND/OR (AO) gate, an AND/OR/inverter (AOI) gate, a D flip-flop, a reset flip-flop, a master-slave flip-flop, a latch, a counter, or a buffer. Logic devices may perform various kinds of signal processing, such as analog signal processing, analog-to-digital conversion, and control.

In the system package 2000 of one or more embodiments, the first semiconductor device 1300 may be referred to as a central processing unit (CPU) chip, a microprocessor unit (MPU) chip, a graphics processing unit (GPU) chip, a neural processing unit (NPU) chip, a system-on-glass (SOG) chip, an application specific integrated circuit (ASIC) chip, an application processor (AP) chip, or a control chip, according to the operation thereof.

The first semiconductor device 1300 may also include devices that support communication. However, embodiments are not limited thereto, and for example, the devices that support communication may be provided in a separate chip, e.g., a modem chip, and the separate chip may be arranged on the base substrate 1200 in a structure coupled to the first semiconductor device 1300.

The first semiconductor device 1300 may include a chip body layer and an active layer. The active layer may be arranged below the chip body layer and may include an integrated circuit layer and a wiring layer. The integrated circuit layer may include the plurality of logic devices described above. The wiring layer may be arranged below the integrated circuit layer and may include multiple layers of wires. Accordingly, the bottom surface of the first semiconductor device 1300 may correspond to a front side that is an active surface, and the top surface of the first semiconductor device 1300 may correspond to a back side that is an inactive surface. For example, the bottom surface of the active layer may correspond to the front side of the first semiconductor device 1300, and the top surface of the chip body layer may correspond to the back side of the first semiconductor device 1300.

The second semiconductor device 1400 may be mounted on the base substrate 1200 via the fourth external connection terminal 1450. As seen in FIG. 4, the second semiconductor device 1400 may be adjacent to the first semiconductor device 1300 and arranged on the left outer portion of the base substrate 1200 in the x-direction. However, as described above, the position of the second semiconductor device 1400 may be switched with the position of the first semiconductor device 1300 in the x-direction. In this case, the second semiconductor device 1400 may be on the left inner portion of the base substrate 1200.

For example, the second semiconductor device 1400 may include a volatile memory device, such as a dynamic random access memory (DRAM) device or a static RAM (SRAM) device, or a non-volatile memory device, such as a flash memory device, a phase-change RAM (PRAM) device, a magnetoresistive RAM (MRAM) device, a ferroelectric RAM (FeRAM) device, or a resistive RAM (RRAM) device. The second semiconductor device 1400 may correspond to a single chip or a package including a plurality of chips. For example, when the second semiconductor device 1400 corresponds to a single chip, the second semiconductor device 1400 may include one memory chip. When the second semiconductor device 1400 corresponds to a package, the second semiconductor device 1400 may include a plurality of memory chips. In the system package 2000 of one or more embodiments, the memory chip of the second semiconductor device 1400 may include, for example, a DRAM chip. However, the type of memory chip of the second semiconductor device 1400 is not limited to the DRAM chip.

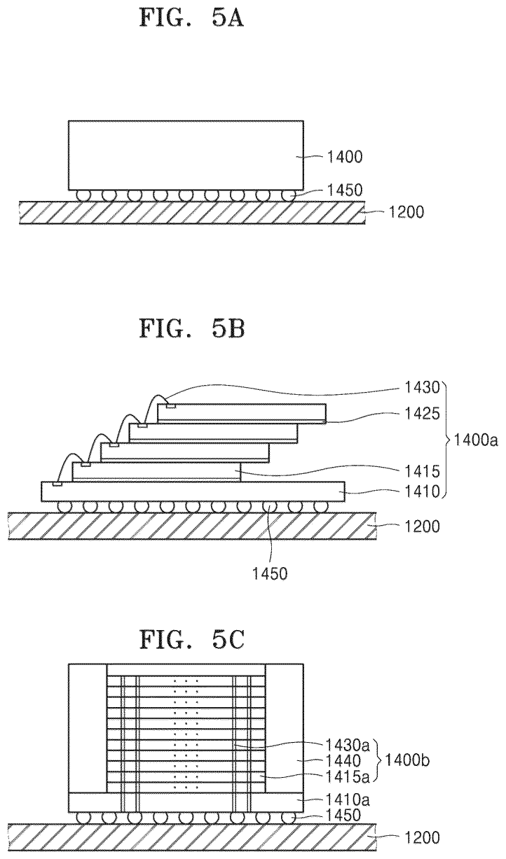

In the system package 2000 of one or more embodiments, the second semiconductor device 1400 may include a high-bandwidth memory (HBM) package as a memory package. However, the second semiconductor device 1400 is not limited to the HBM package. For example, as a memory package, the second semiconductor device 1400 may have a general package structure. For example, the second semiconductor device 1400 may include an upper package substrate and a plurality of memory chips stacked on the upper package substrate. The memory chips may be stacked on the upper package substrate via a bonding wire or via a bump and a TSV. The single-chip structure or the package structure of the second semiconductor device 1400 is described in detail with reference to FIGS. 5A to 5C.

The sealant 1500 may be on the base substrate 1200 and may seal the semiconductor package 1000, the first semiconductor device 1300, and the second semiconductor device 1400. For example, the sealant 1500 may be on the base substrate 1200 and may be adjacent to and surround the side surface of the semiconductor package 1000 and fill between the base substrate 1200 and the semiconductor package 1000 and between first external connection terminals 150. The sealant 1500 may also be adjacent to and surround the side surface of each of the first semiconductor device 1300 and the second semiconductor device 1400 and fill between the base substrate 1200 and the first semiconductor device 1300, between the base substrate 1200 and the second semiconductor device 1400, between third external connection terminals 1350, and between fourth external connection terminals 1450. As shown in FIG. 4, the top surface of each of the semiconductor package 1000, the first semiconductor device 1300, and the second semiconductor device 1400 may be exposed by the sealant 1500. However, embodiments are not limited thereto, and for example, the top surface of at least one of the first semiconductor device 1300 and the second semiconductor device 1400 may be covered by the sealant 1500.

The sealant 1500 may include an insulating material, for example, thermosetting resin such as epoxy resin, thermoplastic resin such as polyimide, or resin including a reinforcing material such as an inorganic filler. For example, the sealant 1500 may include an Ajinomoto build-up film (ABF), flame retardant 4 (FR-4), or bismaleimide triazine (BT). The sealant 1500 may include a molding material, such as an epoxy mold compound (EMC), or a photosensitive material, such as a photo-imageable encapsulant (PIE). However, the material of the sealant 1500 is not limited to those mentioned above.

FIGS. 5A to 5C are detailed cross-sectional views showing the structures of a second semiconductor device of the system package 2000 of FIG. 4. FIGS. 1 and 4 are also referred to, and redundant descriptions already given with reference to FIGS. 1 to 4 are brief or omitted.

Referring to FIG. 5A, in the system package 2000 of one or more embodiments, the second semiconductor device 1400 may include one memory chip. For example, the memory chip may include a volatile memory device, such as a DRAM device or an SRAM device, or a non-volatile memory device, such as a flash memory device. In the system package 2000 of one or more embodiments, the memory chip of the second semiconductor device 1400 may include, for example, a DRAM chip. The second semiconductor device 1400 may be mounted on the base substrate 1200 in a flip-chip bonding structure using the fourth external connection terminal 1450. The fourth external connection terminal 1450 may include a pillar and solder or only solder.

Referring to FIG. 5B, a second semiconductor device 1400a may include a semiconductor package having a wire bonding structure. For example, the second semiconductor device 1400a may include an upper package substrate 1410 and a plurality of memory chips 1415 stacked on the upper package substrate 1410. A memory chip 1415 may be mounted on the upper package substrate 1410 in a wire bonding structure using an adhesive layer 1425 and a wire 1430. For example, the memory chip 1415 of the second semiconductor device 1400a may include a volatile memory chip, such as a DRAM chip or an SRAM chip, or a non-volatile memory chip, such as a flash memory chip. In the system package 2000 of one or more embodiments, the memory chip 1415 of the second semiconductor device 1400a may include, for example, a DRAM chip. The second semiconductor device 1400a may include an inner sealant that is on the upper package substrate 1410 and seals the memory chips 1415 and the wire 1430. However, for convenience, the inner sealant is omitted from FIG. 5B.

Although four memory chips 1415 are stacked on the upper package substrate 1410 in FIG. 5B, the number of memory chips 1415 is not limited to 4. For example, three or less memory chips 1415 or at least five memory chips 1415 may be stacked on the upper package substrate 1410. The memory chips 1415 are not limited to a step structure and may be stacked on the upper package substrate 1410 in a zigzag structure or a structure combining a step structure and a zigzag structure. The second semiconductor device 1400a of a package structure may also be mounted on the base substrate 1200 via the fourth external connection terminal 1450.

Referring to FIG. 5C, a second semiconductor device 1400b may include an HBM package. For example, the second semiconductor device 1400b may include a base chip 1410a, a plurality of core chips 1415a stacked on the base chip 1410a, and an inner sealant 1440. The base chip 1410a and the core chips 1415a may have a through electrode 1430a therein. Among the core chips 1415a, the topmost core chip 1415a may not have a through electrode 1430a therein.

The base chip 1410a may include logic devices. Accordingly, the base chip 1410a may correspond to a logic chip. In this case, the base chip 1410a may be below the core chips 1415a and may combine and transmit the signals of the core chips 1415a to the outside and transmit signals and power from the outside to the core chips 1415a. Accordingly, the base chip 1410a may be referred to as a buffer chip or a control chip. Each of the core chips 1415a may correspond to a memory chip. For example, each of the core chips 1415a may correspond to a DRAM chip.

Each of the core chips 1415a may be stacked on the base chip 1410a or a core chip 1415a therebelow through pad-to-pad bonding, HCB, bonding using a connection terminal, or bonding using an anisotropic conductive film (ACF). The ACF allows electricity to flow in only one direction and may refer to a conductive film that is formed by mixing fine conductive particles with adhesive resin.

The core chips 1415a on the base chip 1410a may be sealed by the inner sealant 1440. However, the top surface of the topmost core chip 1415a may not be covered and exposed by the inner sealant 1440. However, embodiments are not limited thereto, and for example, the top surface of the topmost core chip 1415a may be covered by the inner sealant 1440.

Although the twelve core chips 1415a are stacked on the base chip 1410a in FIG. 5C, the number of core chips 1415a is not limited to 12. For example, eleven or less or at least 13 core chips 1415a may be stacked on the base chip 1410a. The fourth external connection terminal 1450 may be arranged on the bottom surface of the base chip 1410a. Accordingly, the second semiconductor device 1400b of the HBM package may also be mounted on the base substrate 1200 via the fourth external connection terminal 1450.

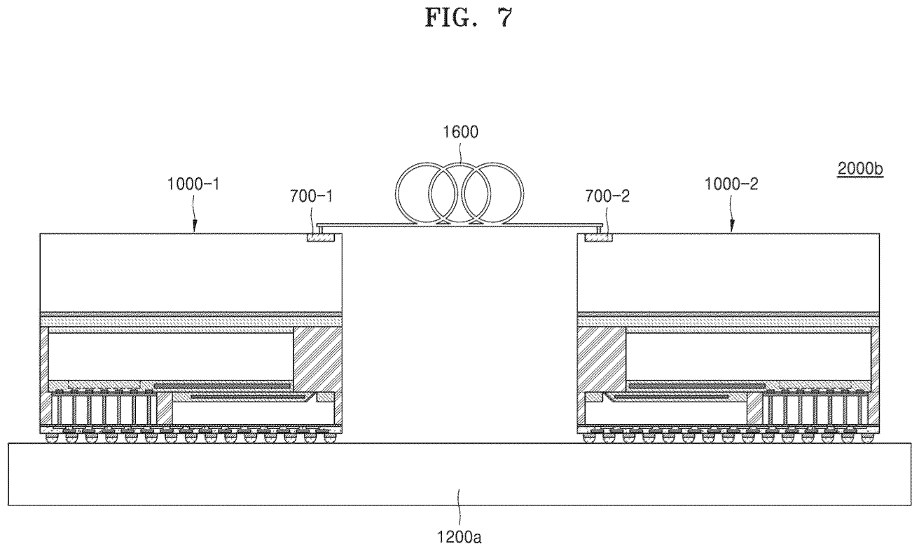

FIGS. 6 and 7 are cross-sectional views of system packages according to embodiments. FIGS. 1 and 4 are also referred to, and redundant descriptions already given with reference to FIGS. 1 to 5C are brief or omitted.

Referring to FIG. 6, a system package 2000a may include the semiconductor package 1000, the package substrate 1100, an interposer 1200, the first semiconductor device 1300, the second semiconductor device 1400, and the sealant 1500. The semiconductor package 1000 may correspond to the semiconductor package 1000 of FIG. 1. However, instead of the semiconductor package 1000 of FIG. 1, the semiconductor package 1000a of FIG. 3 may be applied to the system package 2000a of one or more embodiments. The interposer 1200, the first semiconductor device 1300, the second semiconductor device 1400, and the sealant 1500 have been described in the description of the system package 2000 of FIG. 4. The interposer 1200 may correspond to the base substrate 1200 of the system package 2000 of FIG. 4.

In the system package 2000a of one or more embodiments, the package substrate 1100 may include, for example, a ceramic substrate, a printed circuit board (PCB), a glass substrate, an interposer substrate, or the like. In one or more embodiments, the package substrate 1100 may include an active wafer such as a silicon wafer. In the system package 2000a of one or more embodiments, the package substrate 1100 may include a PCB. However, the package substrate 1100 is not limited to the PCB.

The package substrate 1100 may include a substrate body layer, a protective layer, and a substrate pad. The substrate body layer may form the body of the package substrate 1100 and may include a wiring layer therein. For example, when the package substrate 1100 includes a PCB, the substrate body layer may include a core layer and a wiring layer.

For example, the core layer may include glass fiber, such as FR-4, and resin. The core layer may include BT resin, polycarbonate (PC) resin, a build-up film such as an ABF, or laminate resin.

The wiring layer may be divided into an upper wiring layer and a lower wiring layer by the core layer. Each of the upper wiring layer and the lower wiring layer may include multiple layers of wires. The number of layers of wires in the upper wiring layer may be the same as or different from the number of layers of wires in the lower wiring layer. The wiring layer may include multiple layers of wires, an interlayer insulating layer insulating the wires from each other, and a vertical via connecting wires in different layers to each other. For example, the wires and the vertical via may include copper (Cu). However, the material of the wires and the vertical via is not limited to Cu. For example, the interlayer insulating layer may include prepreg (PPG). However, the material of the interlayer insulating layer is not limited to the PPG.

In one or more embodiments, the core layer may be omitted. In one or more embodiments, the package substrate 1100 may correspond to a redistribution substrate. In this case, the substrate body layer may not include a separate core layer and may include an interlayer insulating layer of PID resin and multiple layers of wires.

The protective layer may be arranged on the top and bottom surfaces of the substrate body layer. For example, the protective layer may include solder resist (SR). However, the material of the protective layer is not limited to the SR. The substrate pad may be arranged on the top and bottom surface of the substrate body layer. The substrate pad may pass through the protective layer. The substrate pad may be connected to wires of the wiring layer of the substrate body layer.

An external connection terminal 1150 may be arranged on the substrate pad on the bottom surface of the substrate body layer. The second external connection terminal 1250 may be arranged on the substrate pad on the top surface of the substrate body layer. The external connection terminal 1150 may connect the system package 2000a to a package substrate of an external system or a main board of an electronic device such as a mobile device. For example, the external connection terminal 1150 may include solder. The material of the external connection terminal 1150 is not limited to the solder.

Referring to FIG. 7, a system package 2000b of one or more embodiments may include two semiconductor packages (e.g., 1000-1 and 1000-2), a base substrate 1200a, and an optical fiber 1600. Each of the two semiconductor packages (1000-1 and 1000-2) may correspond to the semiconductor package 1000 of FIG. 1. However, instead of the semiconductor package 1000 of FIG. 1, the semiconductor package 1000a of FIG. 3 may be applied to the system package 2000b of one or more embodiments.

In the system package 2000b of one or more embodiments, the base substrate 1200a may support the two semiconductor packages (1000-1 and 1000-2). The base substrate 1200a may correspond to an interposer, a package substrate, or a support block substrate. The interposer and the package substrate have been described in the description of the system packages 2000 and 2000a of FIGS. 4 and 6. Because the support block substrate serves as a support, a component may not be arranged in the support block substrate. Accordingly, the support block substrate may include Si, glass, ceramic, a polymer, or the like, and a component such as a wire may not be inside the support block substrate.

In the system package 2000b of one or more embodiments, a first semiconductor package 1000-1 may include a first optical coupler 700-1, and a second semiconductor package 1000-2 may include a second optical coupler 700-2. The first optical coupler 700-1 and the second optical coupler 700-2 may be optically coupled to the optical fiber 1600. Accordingly, optical communication may be implemented between the first semiconductor package 1000-1 and the second semiconductor package 1000-2 through the optical fiber 1600. In the system package 2000b of one or more embodiments, the optical fiber 1600 may include an FAU that transmits optical signals.

Although the two semiconductor packages (1000-1 and 1000-2) are arranged on the base substrate 1200a in the system package 2000b of one or more embodiments, the number of semiconductor packages on the base substrate 1200a is not limited to 2. Apart from a semiconductor package, the first and second semiconductor devices 1300 and 1400 of the system package 2000 of FIG. 4 may be arranged on the base substrate 1200a. In this case, the base substrate 1200a may correspond to an interposer or a package substrate.

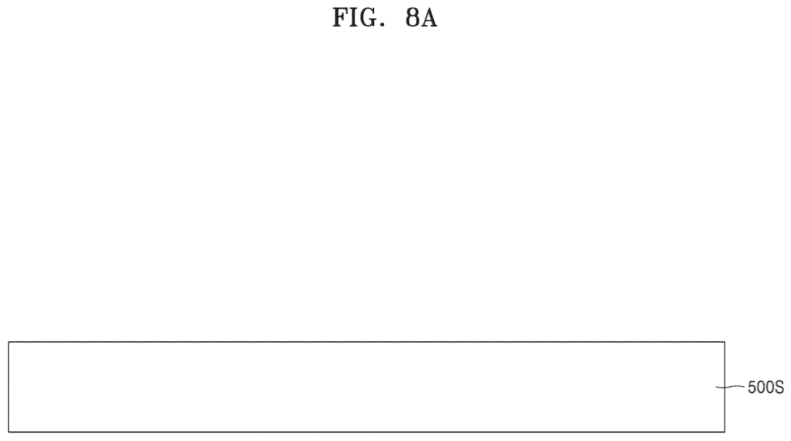

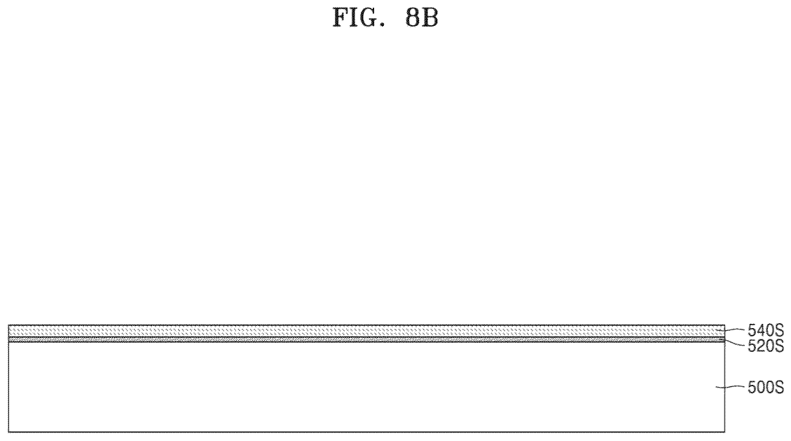

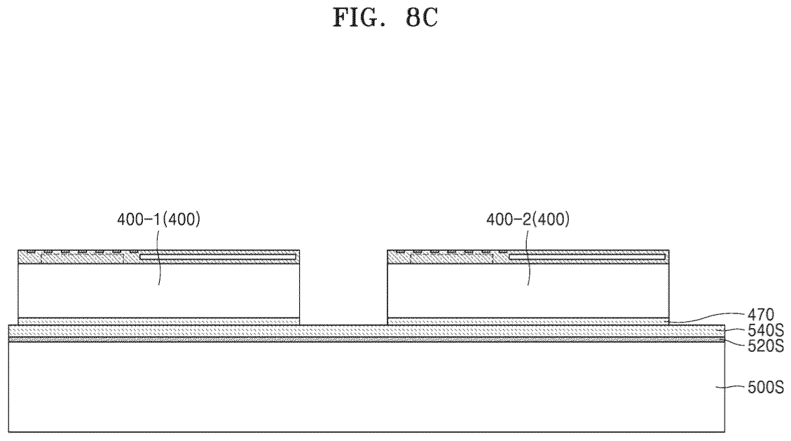

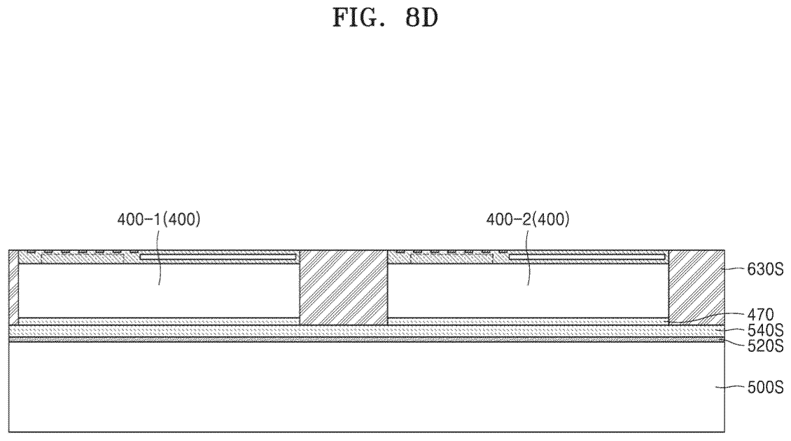

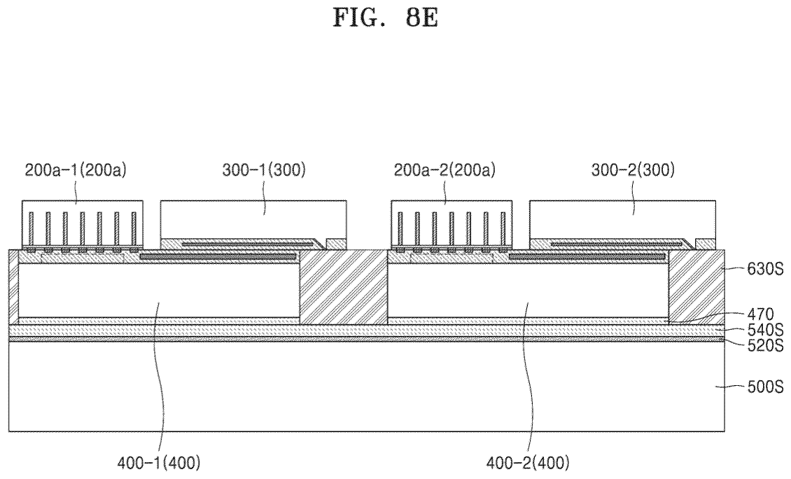

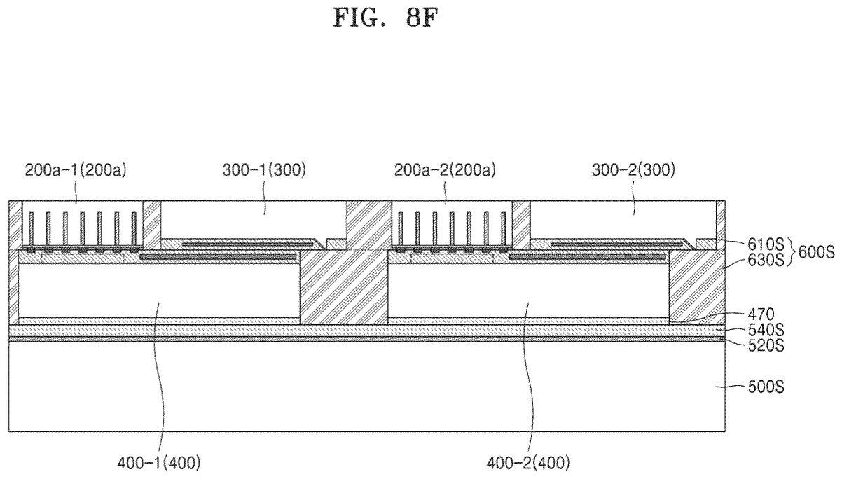

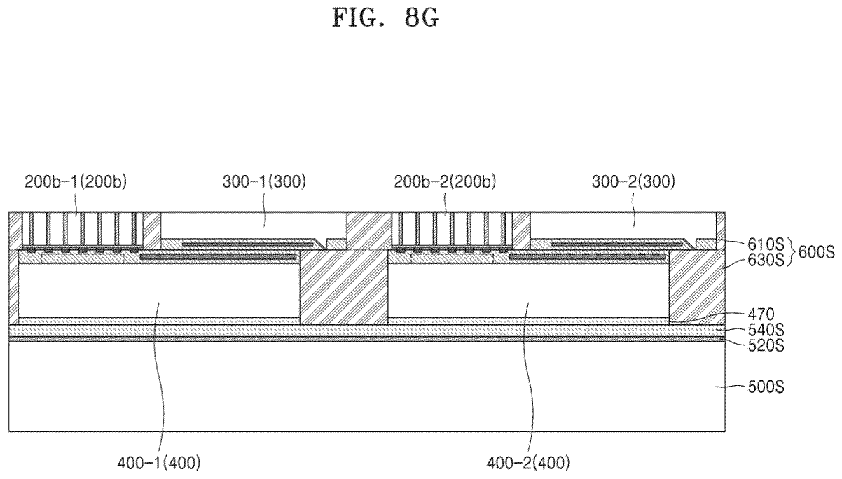

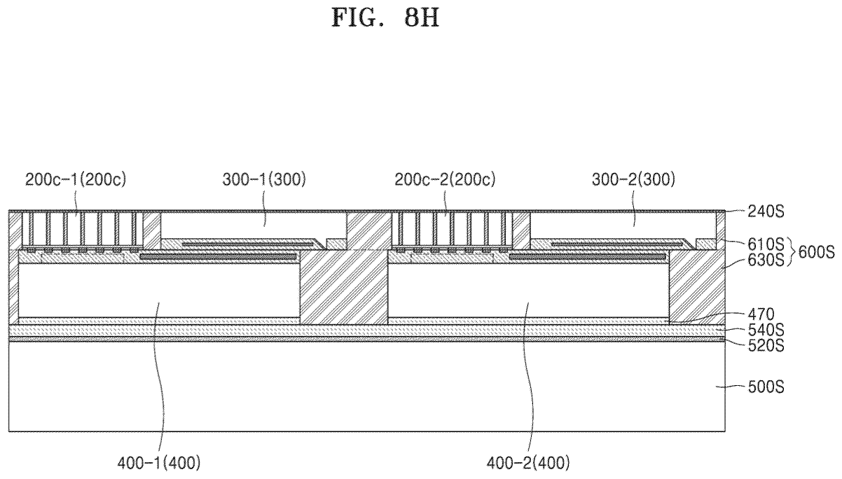

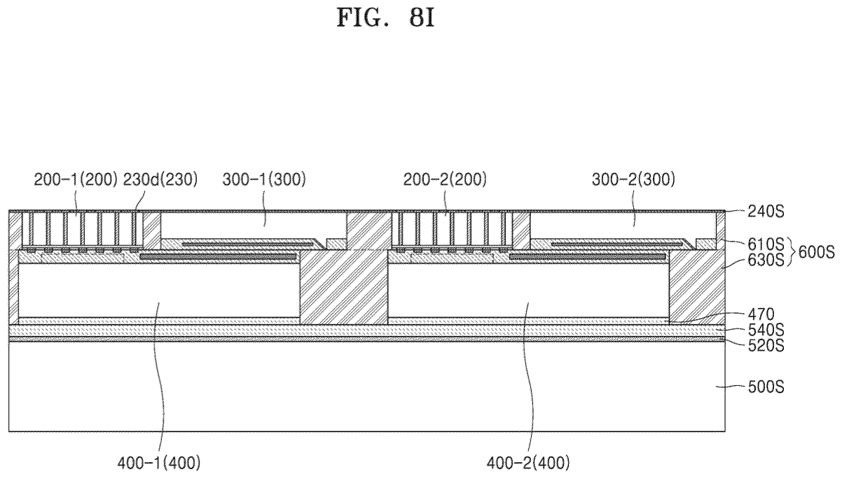

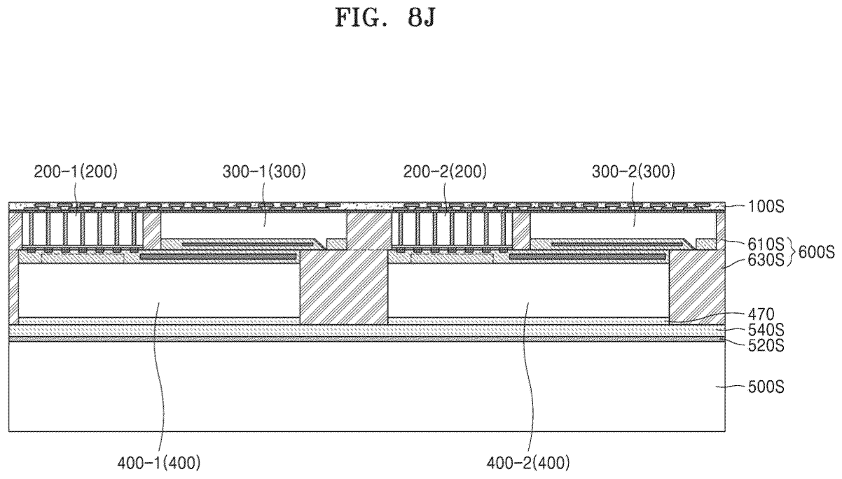

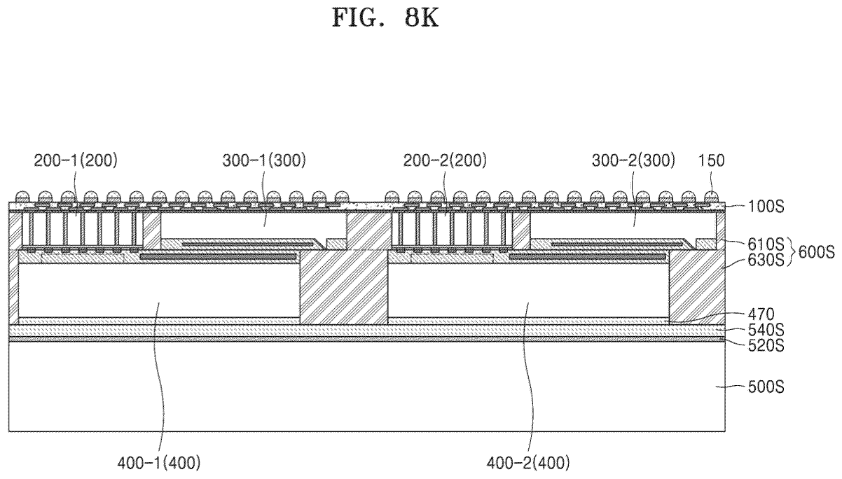

FIGS. 8A to 8L are schematic cross-sectional views of stages in a method of manufacturing a semiconductor package, according to one or more embodiments. FIG. 1 is also referred to, and redundant descriptions already given with reference to FIGS. 1 to 7 are brief or omitted.

Referring to FIG. 8A, in the method of one or more embodiments, a carrier substrate 500S may be prepared. The carrier substrate 500S may include Si. The carrier substrate 500S may serve as a support substrate during stages in the method of manufacturing a semiconductor package and may become the transparent support layer 500 of the semiconductor package 1000 in the final stage. The carrier substrate 500S may have a wafer-level size and correspond to a plurality of transparent support layers 500.

Referring to FIG. 8B, after the carrier substrate 500S is formed, an anti-reflective layer 520S and a second bonding interface 540S may be formed on the top surface of the carrier substrate 500S. The anti-reflective layer 520S and the second bonding interface 540S have been described in the description of the semiconductor package 1000 of FIG. 1. However, in the stage of FIG. 8B, the anti-reflective layer 520S and the second bonding interface 540S may each have a wafer-level size. In one or more embodiments, the anti-reflective layer 520S may be omitted.

Compared to the transparent support layer 500 of the semiconductor package 1000 of FIG. 1, the carrier substrate 500S may be upside down. Accordingly, the top surface of the carrier substrate 500S may correspond to the bottom surface of the transparent support layer 500.

Thereafter, referring to FIG. 8C, PIC chips 400 may be bonded to and stacked on the carrier substrate 500S. Each of the PIC chips 400 may be stacked through bonding between the first bonding interface 470 on the bottom surface of each PIC chip 400 and the second bonding interface 540S of the carrier substrate 500S. The PIC chip 400 and the second bonding interface 540S have been described in the description of the semiconductor package 1000 of FIG. 1.

Referring to FIG. 8D, after the PIC chips 400 are stacked, a second insulating layer 630S may be formed on the carrier substrate 500S to be provided on and cover the side surfaces of the PIC chips 400. The second insulating layer 630S may have a wafer-level size and cover side surfaces of all the PIC chips 400 on the carrier substrate 500S.

The process of forming the second insulating layer 630S is described in detail below. Firstly, a second insulating material layer may be applied to the resultant structure of FIG. 8C to cover the top and side surfaces of the PIC chips 400. The second insulating material layer may be applied using CVD or spin coating. For example, the second insulating material layer may include SiO₂, SiCN, SiON, SiN, or a polymer. In the case of SiO₂, SiCN, SiON, or SiN, CVD may be used. In the case of a polymer, spin coating may be used.

An upper portion of the second insulating material layer may be removed to expose the top surfaces of the PIC chips 400. The upper portion of the second insulating material layer may be removed by etching and/or chemical mechanical polishing. The second insulating layer 630S may be completed by removing the upper portion of the second insulating material layer. Accordingly, the top surfaces of the PIC chips 400 may be exposed by the second insulating layer 630S. The top surface of the second insulating layer 630S may be substantially coplanar with the top surfaces of the PIC chips 400.

Referring to FIG. 8E, after the second insulating layer 630S is formed, EIC chips 200a and optical path bridge chips 300 may be stacked on the PIC chips 400 and the second insulating layer 630S. Each of the EIC chips 200a may be stacked on a PIC chip 400 corresponding thereto through pad-to-pad bonding or HCB. Each of the optical path bridge chips 300 may be stacked on a PIC chip 400 corresponding thereto through insulator-to-insulator bonding. The first WG 320 of each optical path bridge chip 300 may be coupled to the second WG 420 of the PIC chip 400 in a structure for evanescent coupling. The other descriptions of the EIC chip 200a and the optical path bridge chip 300 have been given in the description of the semiconductor package 1000 of FIG. 1. In one or more embodiments, the EIC chip 200a may be stacked on the PIC chip 400 through the connection terminal 450.

Referring to FIG. 8F, after the EIC chips 200a and the optical path bridge chips 300 are stacked, a first insulating layer 610S may be formed on the PIC chips 400 and the second insulating layer 630S to be provided on and cover the side surfaces of the EIC chips 200a and the side surfaces of the optical path bridge chips 300. The first insulating layer 610S may have a wafer-level size and cover the side surfaces of all the EIC chips 200a and the side surfaces of all the optical path bridge chips 300 on the PIC chips 400 and the second insulating layer 630S. The method of forming the first insulating layer 610S may be similar to the method of forming the second insulating layer 630S.

The process of forming the first insulating layer 610S is described in detail below. Firstly, a first insulating material layer may be applied to the resultant structure of FIG. 8E to be provided on and cover the top and side surfaces of the EIC chips 200a and the optical path bridge chips 300. Thereafter, the first insulating layer 610S may be completed by removing an upper portion of the first insulating material layer to expose the top surfaces of the EIC chips 200a and the optical path bridge chips 300.

The material of the first insulating layer 610S may be the same as or different from the material of the second insulating layer 630S. Even when the material of the first insulating layer 610S is the same as the material of the second insulating layer 630S, the first insulating layer 610S and the second insulating layer 630S may have different material characteristics from each other due to a difference in manufacturing processes For example, when the first insulating layer 610S and the second insulating layer 630S are formed using CVD under different CVD process conditions, the stress characteristic may be controlled to be different between the first insulating layer 610S and the second insulating layer 630S with respect to compressive strength or tensile stress. When the first insulating layer 610S and the second insulating layer 630S include different materials from each other or are controlled to have different material characteristics through manufacturing processes, there may be a boundary surface between the first insulating layer 610S and the second insulating layer 630S.

Referring to FIG. 8G, after the first insulating layer 610S is formed, a process may be performed to expose the through electrode 220 of each of the EIC chips 200a. The process of exposing the through electrode 220 may be carried out through a grinding process and an Si recess process.

The process of exposing the through electrode 220 is described in detail below. Firstly, an upper portion of the first body layer 201 of each EIC chip 200a may be primarily removed by a grinding process. At this time, the through electrode 220 may not be exposed. Thereafter, the through electrode 220 may be exposed by additionally removing an upper portion of the first body layer 201 by using an Si recess process. For example, the Si recess process may be carried out through a dry etching process. However, embodiments are not limited thereto, and for example, a wet etching process may be used for the Si recess process.

After the grinding process and the Si recess process, EIC chips 200b having less thickness than the EIC chips 200a may be formed. After the Si recess process, the through electrode 220 may slightly protrude from the top surface of the first body layer 201. However, for convenience, it is illustrated in FIG. 8G that the through electrode 220 does not protrude. The grinding process and the Si recess process may also be performed on the optical path bridge chips 300 and the first insulating layer 610. Accordingly, after the grinding process and the Si recess process, the optical path bridge chips 300 and the first insulating layer 610S may also be thinner.

Referring to FIG. 8H, after the through electrode 220 is exposed, a protective layer 240S may be formed on the EIC chips 200a, the optical path bridge chips 300, and the first insulating layer 610S. The protective layer 240S may be provided on and cover all of the EIC chips 200a, the optical path bridge chips 300, and the first insulating layer 610S. The other descriptions of the protective layer 240S have been given in the description of the semiconductor package 1000 of FIG. 1. The protective layer 240S may form the protective layer 240 on the first body layer 201 in each of EIC chips 200c.

Referring to FIG. 8I, after the protective layer 240S is formed, the first pad 230, e.g., the first lower pad 230d, may be formed on each of the EIC chips 200c. The first lower pad 230d may pass through the protective layer 240S and may be connected to the through electrode 220. The first lower pad 230d has been described in the description of the semiconductor package 1000 of FIG. 1. EIC chips 200 may be completed by forming the first lower pad 230d.

Referring to FIG. 8J, after the first lower pad 230d is formed, a redistribution substrate 100S may be formed on the first lower pad 230d and the protective layer 240S. The redistribution substrate 100S may have a wafer-level size. The description of the redistribution substrate 100S has been given in the description of the semiconductor package 1000 of FIG. 1.

Referring to FIG. 8K, after the redistribution substrate 100S is formed, the first external connection terminal 150 may be formed on the redistribution substrate 100S. The first external connection terminal 150 has been described in the description of the semiconductor package 1000 of FIG. 1.

Referring to FIG. 8L, the semiconductor package 1000 may be manufactured by singulation using a sawing process S. For example, the semiconductor package 1000 may correspond to the semiconductor package 1000 of FIG. 1. When each of the EIC chips 200a is stacked on a PIC chip 400 via the connection terminal 450, the semiconductor package 1000a of FIG. 3 may be manufactured in the stage of FIG. 8I. The singulation using the sawing process may be carried out in a ring mount 3000. The ring mount 3000 may include a support ring and a dicing tap provided on and covering an opening of the support ring. For convenience, only the dicing tape of the ring mount 3000 is illustrated in FIG. 8L.

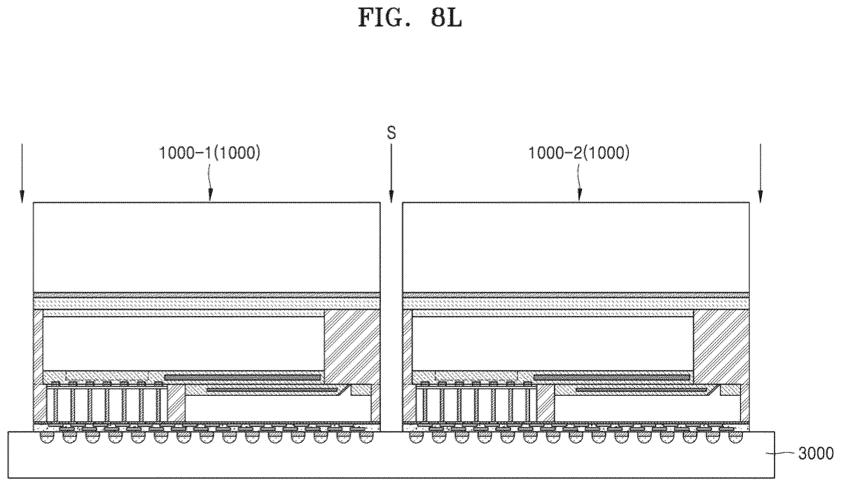

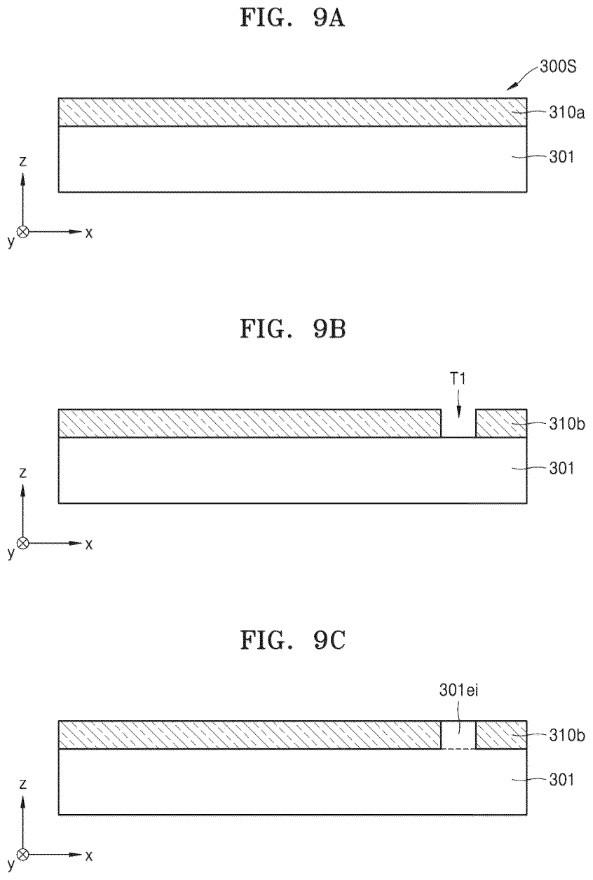

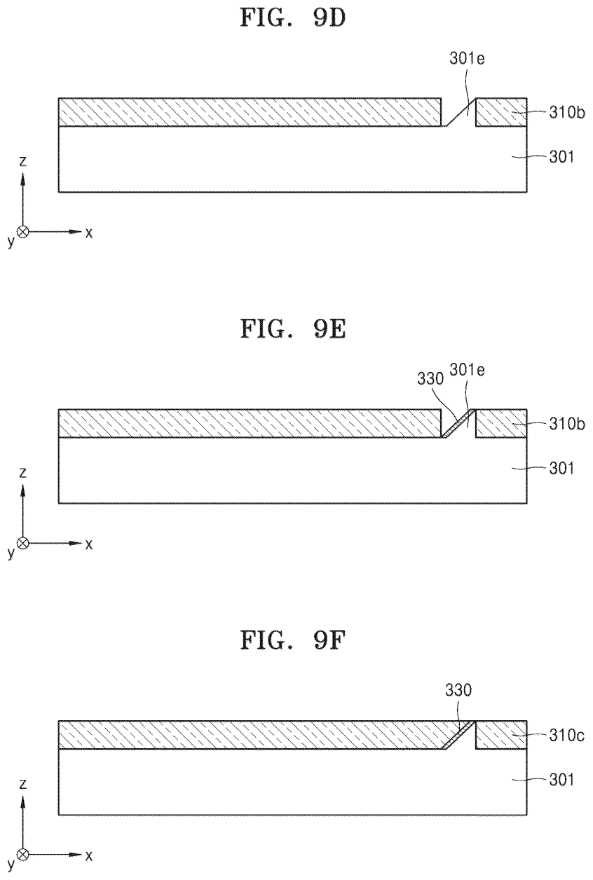

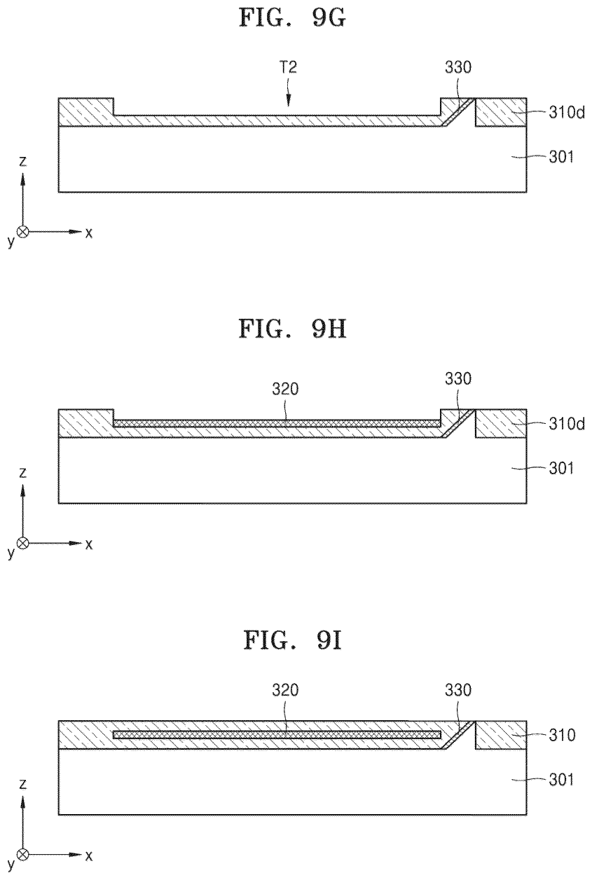

FIGS. 9A to 9I are schematic cross-sectional views of stages in a method of manufacturing an optical path bridge chip, according to one or more embodiments. FIG. 1 is also referred to, and redundant descriptions already given with reference to FIGS. 1 to 8L are brief or omitted.

Referring to FIG. 9A, in the method of manufacturing an optical path bridge chip, a wafer 300S having a silicon-on-insulator (SOI) structure may be prepared. The wafer 300S may include the second body layer 301 and a first BOX layer 310a. The descriptions of the second body layer 301 and the first BOX layer 310a have been given in the description of the semiconductor package 1000 of FIG. 1.

Referring to FIG. 9B, the first BOX layer 310a may be patterned by a photolithography process. A first BOX layer 310b having a first trench T1 may be formed by patterning the first BOX layer 310a. The first trench T1 may expose the top surface of the second body layer 301. The first trench T1 may have a width corresponding to the width of the first WG 320, which is formed later, in the y-direction.

Referring to FIG. 9C, after the first trench T1 is formed, an initial support epitaxial layer 301ei may be formed in the first trench T1. The initial support epitaxial layer 301ei may be formed by epitaxial growth. Accordingly, the initial support epitaxial layer 301ei may include Si.

Referring to FIG. 9D, after the initial support epitaxial layer 301ei is formed, a support epitaxial layer 301e may be formed by an etching process. In the etching process, the initial support epitaxial layer 301ei may be rapidly etched in one direction based on the crystal lattice structure of the initial support epitaxial layer 301ei so that the support epitaxial layer 301e having a slope at an angle with respect to an upper surface of the second body layer 301 may be formed, as shown in FIG. 9D.

Referring to FIG. 9E, continuously, the reflector 330 may be formed by forming a metal plate on the support epitaxial layer 301e. For example, the metal plate on the support epitaxial layer 301e may be formed by physical vapor deposition (PVD).

Referring FIG. 9F, after the reflector 330 is formed, the remaining portion of the first trench T1 may be filled using a gapfill process. For example, the gapfill process may be carried out by CVD. In the gapfill process, the remaining portion of the first trench T1 may be filled by the material, e.g., SiO₂, of a first BOX layer 310c.

Referring to FIG. 9G, the first BOX layer 310c may be patterned by a photolithography process. A first BOX layer 310d having a second trench T2 may be formed by patterning the first BOX layer 310c. The second trench T2 may be formed in a portion in which the first WG 320 is formed. The second trench T2 may be formed by removing an upper portion of the first BOX layer 310c. Accordingly, the bottom of the second trench T2 may still be a part of the first BOX layer 310d. The right end of the second trench T2 in the x-direction may not be in contact with the reflector 330 but be separated from the reflector 330.

Referring to FIG. 9H, after the second trench T2 is formed, the first WG 320 may be formed on the bottom of the second trench T2. The first WG 320 may be formed by depositing a WG material, e.g., SiN, on the bottom of the second trench T2 to a uniform thickness by using CVD.

Referring to FIG. 9I, after the first WG 320 is formed, the remaining portion of the second trench T2 may be filled using a gapfill process. For example, the gapfill process may be carried out by CVD. In the gapfill process, the remaining portion of the second trench T2 may be filled by the material, e.g., SiO₂, of the first BOX layer 310d. An optical path bridge chip may be completed by filling the second trench T2. However, because the processes of FIGS. 9A to 9H are formed at a wafer level, the optical path bridge chip 300 may be completely formed by singulation using a sawing process.

While embodiments have been described with reference to the figures, it will be understood by those of ordinary skill in the art that various changes in form and details may be made therein without departing from the spirit and scope as defined by the following claims and their equivalents.

What is claimed is:

1. A semiconductor package comprising:
a redistribution substrate;
an electronic integrated circuit (EIC) chip on the redistribution substrate;
an optical path bridge chip on the redistribution substrate, the optical path bridge chip being at a side of the EIC chip in a horizontal direction and comprising a first waveguide (WG) extending in the horizontal direction;
a photonic integrated circuit (PIC) chip on the EIC chip and the optical path bridge chip, the PIC chip comprising a second WG extending in the horizontal direction; and
a transparent support layer on the PIC chip,
wherein a portion of the first WG overlaps a portion of the second WG in a vertical direction, and
wherein the PIC chip is configured to provide an optical signal to be transmitted to an outside of the semiconductor package through the second WG, the first WG, and the transparent support layer.

2. The semiconductor package of claim 1, wherein the optical path bridge chip further comprises:
a reflector on the first WG in the horizontal direction, and
wherein the reflector is configured to reflect the optical signal in the vertical direction to be incident to the transparent support layer.

3. The semiconductor package of claim 1, wherein the first WG and the second WG are tapered to the portion of the first WG overlapping the portion of the second WG.

4. The semiconductor package of claim 1, wherein the optical signal is configured to be transmitted through evanescent coupling between the PIC chip and the optical path bridge chip.

5. The semiconductor package of claim 1, wherein the EIC chip comprises:
a first body layer, an active layer on a top surface the first body layer;
a lower pad on a bottom surface of the first body layer;
an upper pad on a top surface of the active layer;
a through electrode passing through the first body layer and connecting the lower pad to the active layer; and
a chip pad included in the PIC chip is connected to the upper pad.

6. The semiconductor package of claim 5, wherein the chip pad included in the PIC chip is connected to the upper pad through one of hybrid copper bonding (HCB) and a connection terminal.

7. The semiconductor package of claim 1, wherein the PIC chip comprises:
a second body layer;
a buried oxide (BOX) layer on a lower surface of the second body layer;
an optical passive device in the BOX layer, the second WG being in the BOX layer; and
a chip pad on a bottom surface of the BOX layer, and
wherein the chip pad is on a portion of the bottom surface of the BOX layer overlapping the EIC chip in the vertical direction and connected to an upper pad of the EIC chip.

8. The semiconductor package of claim 1, further comprising:
a first insulating layer on the redistribution substrate, a side surface of the EIC chip, and a side surface of the optical path bridge chip; and
a second insulating layer on the first insulating layer, the optical path bridge chip, and a side surface of the PIC chip,
wherein the second insulating layer is transparent and is configured to provide an optical path from the optical path bridge chip to the transparent support layer.

9. The semiconductor package of claim 1, wherein the transparent support layer is bonded to the PIC chip via a bonding interface layer, and
wherein the transparent support layer comprises an anti-reflective layer at a bottom of the transparent support layer.

10. The semiconductor package of claim 1, further comprising:
an optical coupler in an upper portion of the transparent support layer and connected to an optical fiber,
wherein the optical coupler is configured to transmit the optical signal to the optical fiber.

11. A semiconductor package comprising:
a redistribution substrate;
an electronic integrated circuit (EIC) chip on the redistribution substrate, the EIC chip comprising a through electrode;
an optical path bridge chip on the redistribution substrate, the optical path bridge chip being at a side of the EIC chip in a horizontal direction and comprising a first waveguide (WG) extending in the horizontal direction;
a photonic integrated circuit (PIC) chip on the EIC chip and the optical path bridge chip, the PIC chip comprising a second WG extending in the horizontal direction;
a multi-insulating layer on the EIC chip, the optical path bridge chip, and the PIC chip; and
a transparent support layer on the PIC chip and the multi-insulating layer,
wherein a portion of the first WG overlaps a portion of the second WG in a vertical direction,
wherein the PIC chip is configured to provide an optical signal to be transmitted to an outside of the semiconductor package through the second WG, the first WG, the multi-insulating layer, and the transparent support layer, and
wherein the through electrode is configured to transmit an electronic signal between the PIC chip and the EIC chip.

12. The semiconductor package of claim 11, wherein the optical path bridge chip further comprises:
a reflector on the first WG in the horizontal direction, and
wherein the reflector is configured to reflect the optical signal in the vertical direction to be incident on the multi-insulating layer.

13. The semiconductor package of claim 11, wherein the optical signal is configured to be transmitted through evanescent coupling between the PIC chip and the optical path bridge chip.

14. The semiconductor package of claim 11, wherein the EIC chip comprises:
a first body layer;
an active layer on a top surface of the first body layer;
a lower pad on a bottom surface of the first body layer;
an upper pad on a top surface of the active layer, and the through electrode, the through electrode passing through the first body layer and connecting the lower pad to the active layer,
wherein the PIC chip comprises:
a second body layer;
a buried oxide (BOX) layer on a bottom surface of the second body layer;
an optical passive device in the BOX layer, the second WG being in the BOX layer; and
a chip pad on a bottom surface of the BOX layer overlapping the EIC chip, and
wherein the chip pad of the PIC chip is connected to the upper pad through one of hybrid copper bonding (HCB) and a connection terminal.

15. The semiconductor package of claim 11, wherein the multi-insulating layer comprises:
a first insulating layer on a side surface of the EIC chip and a side surface of the optical path bridge chip; and
a second insulating layer on the first insulating layer, the optical path bridge chip, and a side surface of the PIC chip,
wherein the second insulating layer is transparent and is configured to provide an optical path from the optical path bridge chip to the transparent support layer.

16. A semiconductor package comprising:
a base substrate;
a first semiconductor device on the base substrate;
a second semiconductor device on the base substrate and a left side of the first semiconductor device in a horizontal direction; and
a first optical communication package on the base substrate and a right side of the first semiconductor device in the horizontal direction, the first optical communication package being configured to perform optical communication,
wherein the first optical communication package comprises:
a redistribution substrate;
an electronic integrated circuit (EIC) chip on the redistribution substrate;
an optical path bridge chip on the redistribution substrate, the optical path bridge chip being at a side of the EIC chip in the horizontal direction and comprising a first waveguide (WG) extending in the horizontal direction;
a photonic integrated circuit (PIC) chip on the EIC chip and the optical path bridge chip, the PIC chip comprising a second WG extending in the horizontal direction;
a multi-insulating layer on the EIC chip, the optical path bridge chip, and the PIC chip; and
a transparent support layer on the PIC chip and the multi-insulating layer,
wherein a portion of the first WG overlaps a portion of the second WG in a vertical direction, and
wherein the PIC chip is configured to provide an optical signal to be transmitted to an outside of the semiconductor package through the second WG, the first WG, the multi-insulating layer, and the transparent support layer.

17. The semiconductor package of claim 16, wherein the optical signal is configured to be transmitted through evanescent coupling between the PIC chip and the optical path bridge chip, and
wherein the optical path bridge chip further comprises:
a reflector on the first WG in the horizontal direction, and
wherein the reflector is configured to reflect the optical signal in the vertical direction to be incident to the multi-insulating layer.

18. The semiconductor package of claim 16, wherein the EIC chip comprises:
a first body layer;
an active layer on a top surface of the first body layer;
a lower pad on a bottom surface of the first body layer;
an upper pad on a top surface of the active layer; and
a through electrode passing through the first body layer and connecting the lower pad to the active layer, and
wherein the PIC chip comprises:
a second body layer;
a buried oxide (BOX) layer on a bottom surface of the second body layer;
an optical passive device in the BOX layer, the second WG being in the BOX layer; and
a chip pad on a bottom surface of the BOX layer overlapping the EIC chip, and
wherein the chip pad of the PIC chip is connected to the upper pad through one of hybrid copper bonding (HCB) and a connection terminal.

19. The semiconductor package of claim 16, wherein the base substrate corresponds to one of a package substrate and an interposer,
wherein the first semiconductor device comprises a logic chip, and
wherein the second semiconductor device comprises a high-bandwidth memory (HBM) package.

20. The semiconductor package of claim 16, further comprising:
a second optical communication package on the base substrate,
wherein the first optical communication package is connected to the second optical communication package through an optical fiber, and
wherein each of the first optical communication package and the second optical communication package comprises an optical coupler in the transparent support layer, the optical coupler being connected to the optical fiber.
